(19) United States
(12) Patent Application Publication
(10) Pub. No.: US 2026/0075896 A1
(43) Pub. Date: Mar. 12, 2026

(54) CONTACT STRUCTURE AND METHOD FOR FABRICATING THE SAME

(71) Applicant: Taiwan Semiconductor Manufacturing Company, Ltd., Hsinchu (TW)

(72) Inventors: Tien-Hung Cheng, Hsinchu City (TW); Kuo-Chiang Tsai, Hsinchu City (TW)

(73) Assignee: Taiwan Semiconductor Manufacturing Company, Ltd., Hsinchu (TW)

(21) Appl. No.: 18/829,296

(22) Filed: Sep. 10, 2024

(51) Int. Cl. H01L 29/06; H01L 21/3065; H01L 21/8238; H01L 27/092; H01L 29/08; H01L 29/423; H01L 29/66; H01L 29/775; H01L 29/786

(52) U.S. Cl. CPC H10D 62/121; H10D 30/014; H10D 30/43; H10D 30/6735; H10D 30/6757; H10D 62/151; H10D 64/017; H10D 84/017; H10D 84/0186; H10D 84/038; H10D 84/85; H10P 50/242

(57) ABSTRACT

A contact structure electrically connected between an underlying source/drain region and an overlying interconnect wiring is provided. The contact structure includes a lower part and an upper part disposed on the lower part. The lower part is electrically connected to the underlying source/drain region, and the upper part is electrically connected to the overlying interconnect wiring. The upper part has a first top width in a widthwise direction of the overlying interconnect wiring, the upper part has a second top width in a lengthwise direction of the overlying interconnect wiring, and the second top width of the upper part is greater than the first top width of the upper part.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon. The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, performance and/or reliability of semiconductor devices should be concerned.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nano-FET) in a three-dimensional view, in accordance with some embodiments.

FIGS. 2, 3, 4, 5A, 5B, 6A, 6B, 7A, 7B, 7C, 8A, 8B, 9A, 9B, 10A, 10B, 10C, 10D, 11A, 11B, 11C, 11D, 12A, 12B, 13A, 13B, 14A, 14B, 14C, 15A, 15B, 16A, 16B, 17A, 17B, 17C, 18A, 18B, 18C, 19A, 19B, 20A, 20B, 20C, 21A, 21B, 21C, 22A, 22B, 22C, 23A, 23B, and 23C illustrate varying views of intermediary steps of manufacturing a nano-FET, in accordance with some embodiments.

FIG. 24 illustrate a cross-sectional view of a nano-FET, in accordance with some alternative embodiments.

FIG. 25 illustrates a perspective view of the upper tier source/drain contact structure 126, in accordance with some embodiments.

FIG. 26 illustrates a perspective view of the upper tier source/drain contact structure 126, in accordance with some alternative embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In various embodiments, source/drain contact structures with novel geometry are formed over nano-FETs. The source/drain contact structures include a lower part and an upper part disposed on the lower part, wherein the lower part is electrically connected to an underlying source/drain region of the nano-FET, the upper part is electrically connected to an overlying interconnect wiring. The upper part has a first top width in a widthwise direction of the overlying interconnect wiring, the upper part has a second top width in a lengthwise direction of the overlying interconnect wiring, and the second top width of the upper part is greater than the first top width of the upper part. Due to the greater second top width of the upper part, leakage issue between the source/drain contact structures and neighboring conductive traces (e.g., gate electrodes and/or interconnect wirings) may be solved by such profile of the source/drain contact structures. As a result, such profile of the source/drain contact structures may reduce bulk resistance of the source-drain contacts as well as interface resistance between the source/drain contact structures and overlying interconnect wirings.

Embodiments are described below in a particular context, a die comprising nano-FETs. Various embodiments may be applied, however, to dies comprising other types of transistors (e.g., stacking transistors, or the like) in lieu of or in combination with the nano-FETs.

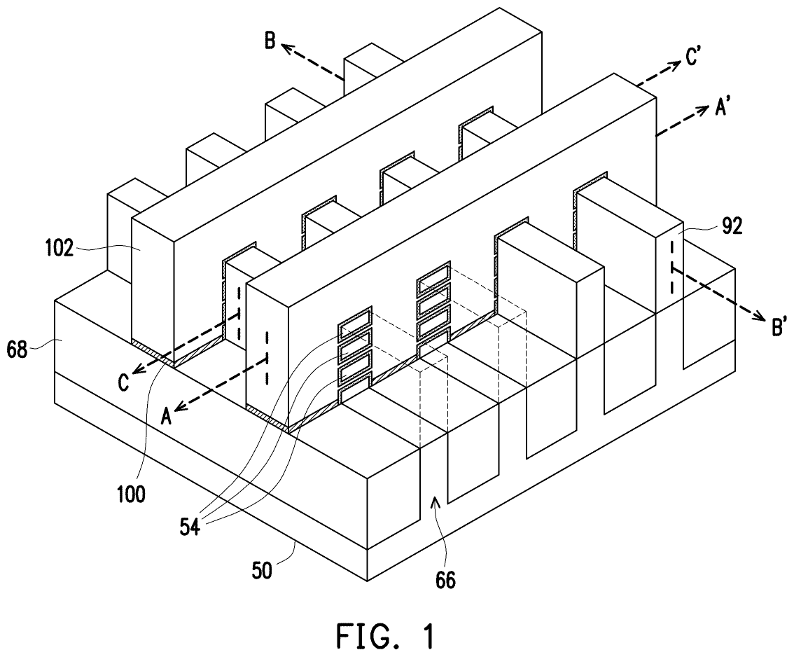

FIG. 1 illustrates an example of nano-FETs (e.g., nanowire FETs, nanosheet FETs, or the like) in a three-dimensional view, in accordance with some embodiments. Certain features are simplified and/or omitted in FIG. 1 for ease of illustration. The nano-FETs comprise nanostructures 54 (e.g., nanosheets, nanowires, or the like) over fins 66 on a substrate 50 (e.g., a semiconductor substrate), wherein the nanostructures 54 act as channel regions for the nano-FETs. The nanostructure 54 may include p-type nanostructures, n-type nanostructures, or a combination thereof. Shallow trench isolation (STI) regions 68 (also referred to as STI structures or STI regions) are disposed between adjacent fins 66, which may protrude above and from between neighboring STI regions 68. Although the STI regions 68 are described/illustrated as being separate from the substrate 50, as used herein, the term “substrate” may refer to the semiconductor substrate alone or a combination of the semiconductor substrate and the isolation regions. Additionally, although a bottom portion of the fins 66 are illustrated as being single, continuous materials with the substrate 50, the bottom portion of the fins 66 and/or the substrate 50 may comprise a single material or a plurality of materials. In this context, the fins 66 refer to the portion extending between the neighboring STI regions 68.

Gate dielectric layers 100 are over top surfaces of the fins 66 and along top surfaces, sidewalls, and bottom surfaces of the nanostructures 54. Gate electrodes 102 are over the gate dielectric layers 100. Epitaxial source/drain regions 92 are disposed on the fins 66 on opposing sides of the gate dielectric layers 100 and the gate electrodes 102. Source/drain region(s) 92 may refer to a source or a drain, individually or collectively dependent upon the context.

FIG. 1 further illustrates reference cross-sections that are used in later figures. Cross-section A-A′ is along a longitudinal axis of a gate electrode 102 and in a direction, for example, perpendicular to the direction of current flow between the epitaxial source/drain regions 92 of a nano-FET. Cross-section B-B′ is perpendicular to cross-section A-A′ and is parallel to a longitudinal axis of a fin 66 of the nano-FET and in a direction of, for example, a current flow between the epitaxial source/drain regions 92 of the nano-FET. Cross-section C-C′ is parallel to cross-section A-A′ and extends through epitaxial source/drain regions of the nano-FETs. Subsequent figures refer to these reference cross-sections for clarity.

Some embodiments discussed herein are discussed in the context of nano-FETs formed using a gate-last process. In other embodiments, a gate-first process may be used. Also, some embodiments contemplate aspects used in planar devices, such as planar FETs or in fin field-effect transistors (FinFETs).

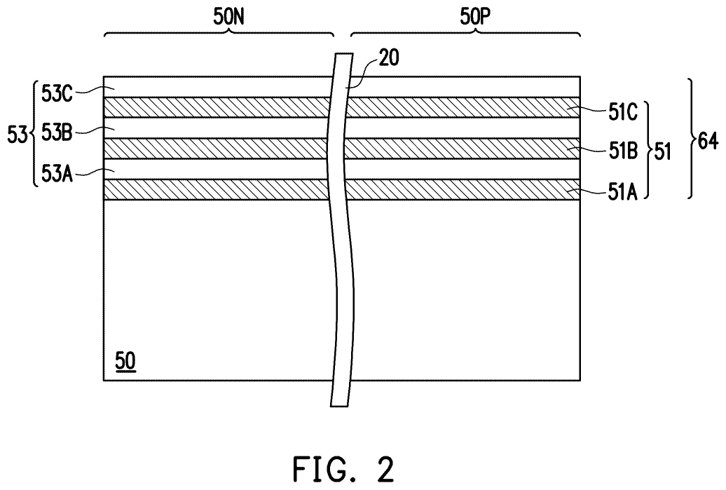

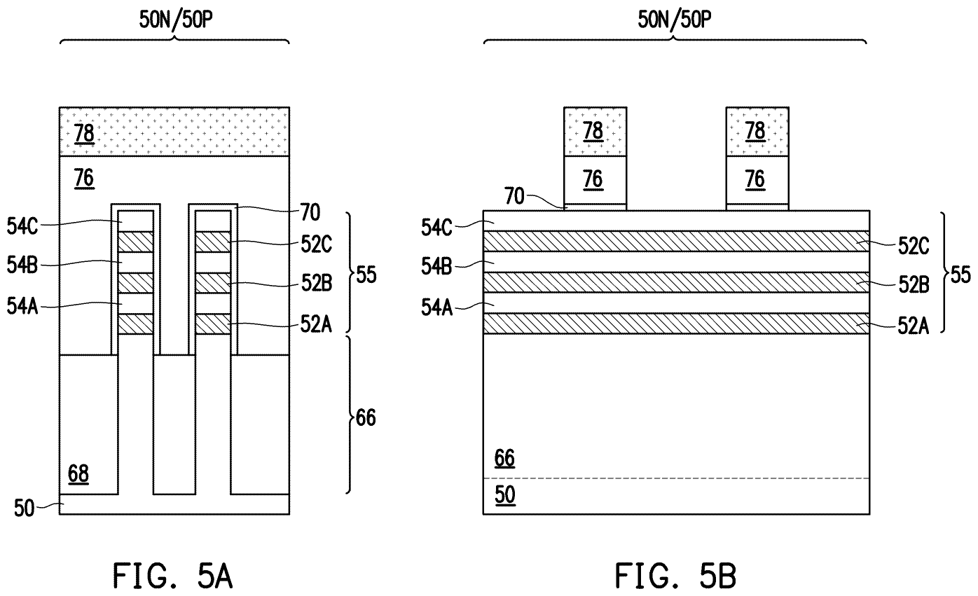

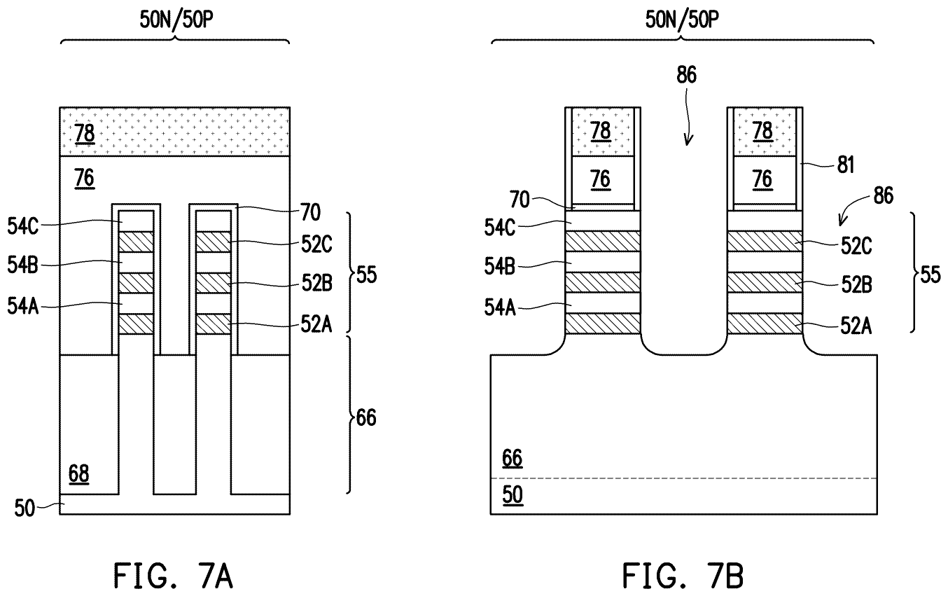

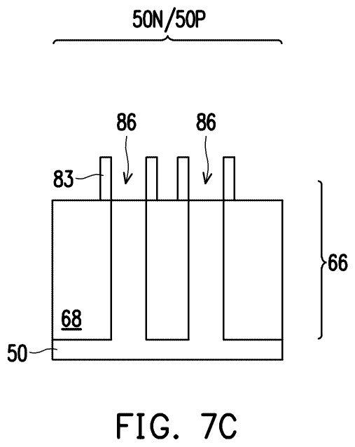

FIGS. 2 through 23C are cross-sectional views of intermediate stages in the manufacturing of nano-FETs, in accordance with some embodiments. FIGS. 2, 3, 4, 5A, 6A, 7A, 8A, 9A, 10A, 11A, 12A, 13A, 14A, 15A, 16A, 17A, 18A, 19A, 20A, 21A, 22A, and 23A illustrate reference cross-section A-A′ illustrated in FIG. 1. FIGS. 5B, 6B, 7B, 8B, 9B, 10B, 10C, 10D, 11B, 12B, 13B, 14B, 14C, 15B 16B, 17B, 17C, 18B, 19B, 20B, 21B, 22B, and 23B illustrate reference cross-section B-B′ illustrated in FIG. 1. FIGS. 7C, 11C, 11D, 18C, 20C, 21C, 22C and 23C illustrate reference cross-section C-C′ illustrated in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided. Subsequent figures describe processing steps that may be performed in either the n-type regions 50N or the p-type regions 50P unless otherwise noted.

Further in FIG. 2, a multi-layer stack 64 is formed over the substrate 50. The multi-layer stack 64 includes alternating layers of first semiconductor layers 51A-C (collectively referred to as first semiconductor layers 51) and second semiconductor layers 53A-C (collectively referred to as second semiconductor layers 53). For purposes of illustration and as discussed in greater detail below, the first semiconductor layers 51 will be removed and the second semiconductor layers 53 will be patterned to form channel regions of nano-FETs in both the n-type region 50N and the p-type region 50P. Nevertheless, in some embodiments, the second semiconductor layers 53 may be removed and the first semiconductor layers 51 may be patterned to form channel regions of nano-FETs in both the n-type region 50N and the p-type region 50P. For example, the channel regions in both the n-type region 50N and the p-type region 50P may have a same material composition (e.g., silicon, or another semiconductor material) and be formed simultaneously.

In other embodiments, the first semiconductor layers 51 may be removed and the second semiconductor layers 53 may be patterned to form channel regions of nano-FETs in the p-type region 50P, and the second semiconductor layers 53 may be removed and the first semiconductor layers 51 may be patterned to form channel regions of nano-FETs in the n-type region 50N. In still other embodiments, the first semiconductor layers 51 may be removed and the second semiconductor layers 53 may be patterned to form channel regions of nano-FETs in the n-type region 50N, and the second semiconductor layers 53 may be removed and the first semiconductor layers 51 may be patterned to form channel regions of nano-FETs in the p-type region 50P. In such embodiments, the channel regions of the n-type region 50N may have a different material composition than the channel regions of the p-type region 50P. The first semiconductor layers 51 and the second semiconductor layers 53 may be selectively removed from each of the n-type region 50N and p-type region 50P through additional masking and etching steps. For example, the channel regions of the n-type region 50N may be silicon channel regions while the channel regions of the p-type region 50P may be silicon germanium channel regions.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like.

In various embodiments, the first semiconductor layers 51 may be formed of a first semiconductor material, such as silicon germanium, or the like, and the second semiconductor layers 53 may be formed of a second semiconductor material, such as silicon, silicon carbon, or the like. The first semiconductor materials and the second semiconductor materials may be materials having a high-etch selectivity to one another. As such, the first semiconductor layers 51 of the first semiconductor material may be removed without significantly removing the second semiconductor layers 53 of the second semiconductor material, thereby allowing the second semiconductor layers 53 to be patterned to form channel regions of the nano-FETs.

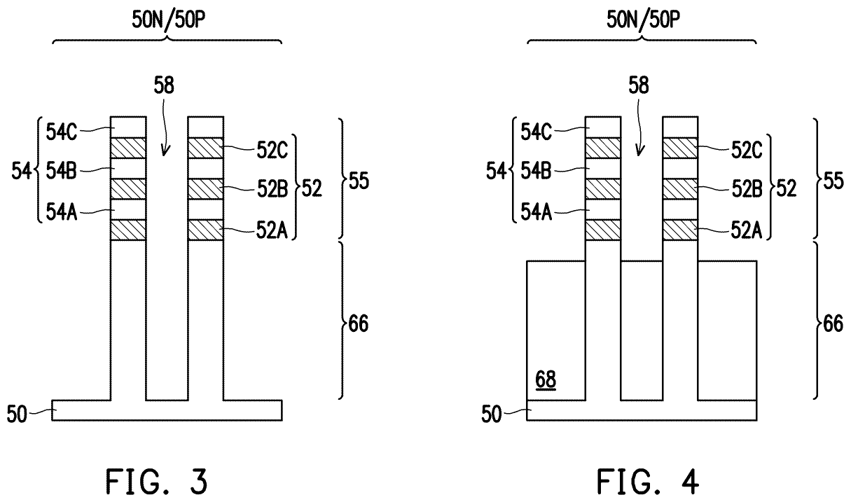

Referring now to FIG. 3, fins 66 are formed in the substrate 50 and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches 58 in the multi-layer stack 64 and the substrate 50. The etching may be any acceptable etch process, such as a reactive ion etch (RIE), neutral beam etch (NBE), the like, or a combination thereof. The etching may be anisotropic. During the etching process, a hard mask may be used to define a pattern of the fins 66 and the nanostructures 55. The hard mask may comprise any suitable insulating material, such as an oxide, a nitride, and oxynitride, and oxycarbonitride, or the like. In some embodiments (not separately illustrated), the hard mask may be a multi-layer structure. The hard mask may be formed over the nanostructures 55 using an acceptable process(es) such as thermal oxidation, physical vapor deposition (PVD), CVD, ALD, combinations thereof, or the like.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, a sacrificial layer is formed over a substrate and patterned using a photolithography process. Spacers are then formed alongside the patterned sacrificial layer using a self-aligned process. The sacrificial layer is then removed, and the remaining spacers may then be used to pattern the fins 66 and the nanostructures 55.

Forming the nanostructures 55 by etching the multi-layer stack 64 may further define first nanostructures 52A-C (collectively referred to as the first nanostructures 52) from the first semiconductor layers 51 and define second nanostructures 54A-C (collectively referred to as the second nanostructures 54) from the second semiconductor layers 53. The first nanostructures 52 and the second nanostructures 54 may further be collectively referred to as the nanostructures 55.

FIG. 3 illustrates the fins 66 having substantially equal widths for illustrative purposes. In some embodiments, widths of the fins 66 in the n-type region 50N may be greater or thinner than the fins 66 in the p-type region 50P. Further, while FIG. 3 illustrates each of the fins 66 and the nanostructures 55 as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

In FIG. 4, shallow trench isolation (STI) regions 68 are formed adjacent the fins 66. The STI regions 68 may be formed by depositing an insulation material over the substrate 50, the fins 66, and nanostructures 55, and between adjacent fins 66 to fill the trenches 58. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments a liner (not separately illustrated) may first be formed along a surface of the substrate 50, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material are level after the planarization process is complete.

The insulation material is then recessed to form the STI regions 68. The insulation material is recessed such that upper portions of fins 66 protrude from between neighboring STI regions 68. Further, the top surfaces of the STI regions 68 may be flat surfaces as illustrated, convex surfaces, concave surfaces (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, dilute hydrofluoric (dHF) acid may be used. Thereafter, an optional hard mask (not separately illustrated) may then be formed over the top surfaces of the STI regions 68 to cover the STI regions 68. The hard mask may be made of a nitride or other material that has etch selectivity to the STI regions 68 (e.g., etch selectivity to a fill material of the STI regions 68).

Further in FIG. 4, appropriate wells (not separately illustrated) may be formed in the fins 66 and/or the nanostructures 55. In embodiments with different well types, different implant steps for the n-type region 50N and the p-type region 50P may be achieved using a photoresist or other masks (not separately illustrated). For example, a photoresist may be formed over the fins 66 and the nanostructures 55 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66 and the nanostructures 55 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

In FIGS. 5A and 5B, dummy gates 76 are formed over and along sidewalls of the nanostructures 55 and the fin 66. To form the dummy gates 76, first, a dummy dielectric layer is formed on the fins 66 and/or the nanostructures 55. The dummy dielectric layer may be, for example, silicon oxide, silicon nitride, a combination thereof, or the like, and may be deposited or thermally grown according to acceptable techniques. A dummy gate layer is formed over the dummy dielectric layer, and a mask layer is formed over the dummy gate layer. The dummy gate layer may be deposited over the dummy dielectric layer and then planarized, such as by a CMP. The mask layer may be deposited over the dummy gate layer. The dummy gate layer may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer may be deposited by physical vapor deposition (PVD), CVD, sputter deposition, or other techniques for depositing the selected material. The dummy gate layer may be made of other materials that have a high etching selectivity from the etching of isolation regions. The mask layer may include, for example, silicon nitride, silicon oxynitride, or the like.

Subsequently, the mask layer may be patterned using acceptable photolithography and etching techniques to form masks 78. The pattern of the masks 78 then may be transferred to the dummy gate layer and to the dummy dielectric layer to form dummy gates 76 and dummy gate dielectrics 70, respectively. The dummy gates 76 cover respective channel regions of the fins 66. The pattern of the masks 78 may be used to physically separate each of the dummy gates 76 from adjacent dummy gates 76. The dummy gates 76 may also have a lengthwise direction substantially perpendicular to the lengthwise direction of respective fins 66. It is noted that the dummy gate dielectrics 70 is shown covering only the fins 66 and the nanostructures 55 for illustrative purposes only. In some embodiments, the dummy gate dielectrics 70 may be deposited such that the dummy gate dielectrics 70 covers the STI regions 68, such that the dummy gate dielectrics 70 extends between the dummy gates 76 and the STI regions 68.

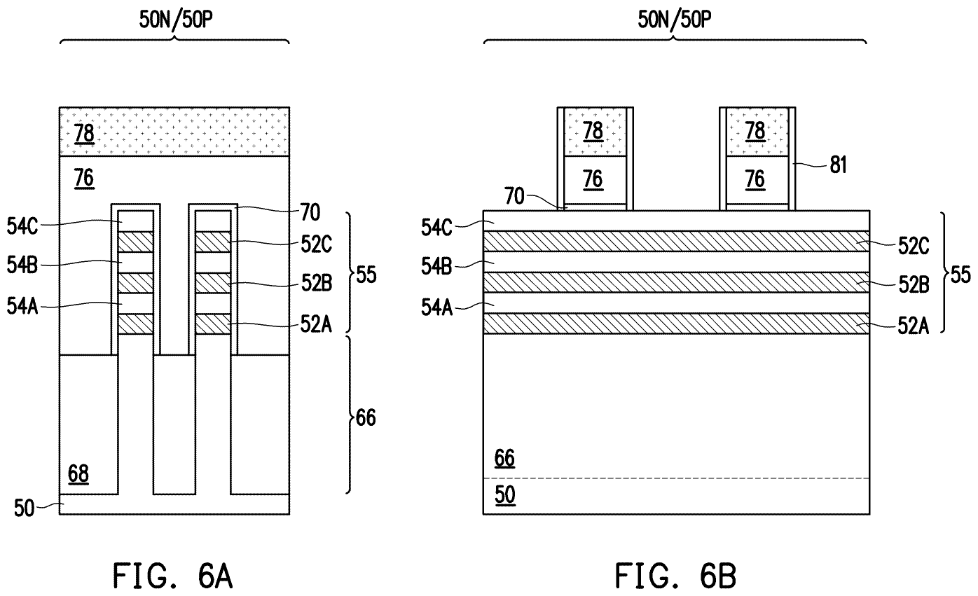

In FIGS. 6A and 6B, gate spacers 81 are formed over the nanostructures 55 and the STI regions 68, on exposed sidewalls of the masks 78 (if present), the dummy gates 76, and the dummy gate dielectrics 70. The gate spacers 81 may be formed by conformally forming one or more dielectric material(s) and subsequently etching the dielectric material(s). Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other insulation materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the dummy gates 76 (thus forming the gate spacers 81). As subsequently described in greater detail, the dielectric material(s), when etched, may also have portions left on the sidewalls of the semiconductor fins 66 and/or the nanostructures 55 (thus forming fin spacers 83, see FIG. 7C). After etching, the fin spacers 83 and/or the gate spacers 81 can have straight sidewalls (as illustrated) or can have curved sidewalls (not separately illustrated).

Further, implants for lightly doped source/drain (LDD) regions (not separately illustrated) may be performed. The LDD implants may be performed before the gate spacers 81 are formed. In embodiments with different device types, similar to the implants for the previously described wells, a mask, such as a photoresist, may be formed over the n-type region 50N, while exposing the p-type region 50P, and appropriate type (e.g., p-type) impurities may be implanted into the semiconductor fins 66 and the nanostructures 55 exposed in the p-type region 50P. The mask may then be removed. Subsequently, a mask, such as a photoresist, may be formed over the p-type region 50P while exposing the n-type region 50N, and appropriate type impurities (e.g., n-type) may be implanted into the semiconductor fins 66 and the nanostructures 55 exposed in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from about 10¹⁵ atoms/cm³ to about 10¹⁹ atoms/cm³. An anneal may be used to repair implant damage and to activate the implanted impurities.

It is noted that the previous disclosure generally describes a process of forming spacers and LDD regions. Other processes and sequences may be used. For example, fewer or additional spacers may be utilized, different sequence of steps may be utilized, additional spacers may be formed and removed, and/or the like. Furthermore, the n-type devices and the p-type devices may be formed using different structures and steps.

In FIGS. 7A-7C, first recesses 86 are formed in the fins 66, the nanostructures 55, and the substrate 50, in accordance with some embodiments. Epitaxial source/drain regions will be subsequently formed in the first recesses 86. The first recesses 86 may extend through the first nanostructures 52 and the second nanostructures 54, and into the substrate 50. As illustrated in FIG. 7C, top surfaces of the STI regions 68 may be level with bottom surfaces of the first recesses 86. In other embodiments, the fins 66 may be etched such that bottom surfaces of the first recesses 86 are disposed above or below the top surfaces of the STI regions 68. The first recesses 86 may be formed by etching the fins 66, the nanostructures 55, and the substrate 50 using anisotropic etching processes, such as RIE, NBE, or the like. The gate spacers 81, the fin spacers 83, and the masks 78 mask portions of the fins 66, the nanostructures 55, and the substrate 50 during the etching processes used to form the first recesses 86. A single etch process or multiple etch processes may be used to etch each layer of the nanostructures 55 and/or the fins 66. Timed etch processes may be used to stop the etching of the first recesses 86 after the first recesses 86 reach a desired depth.

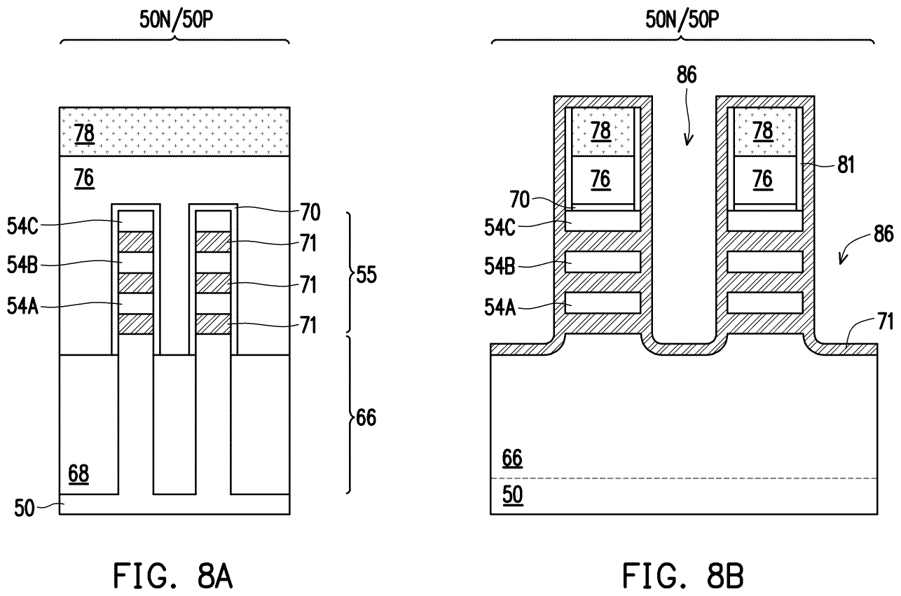

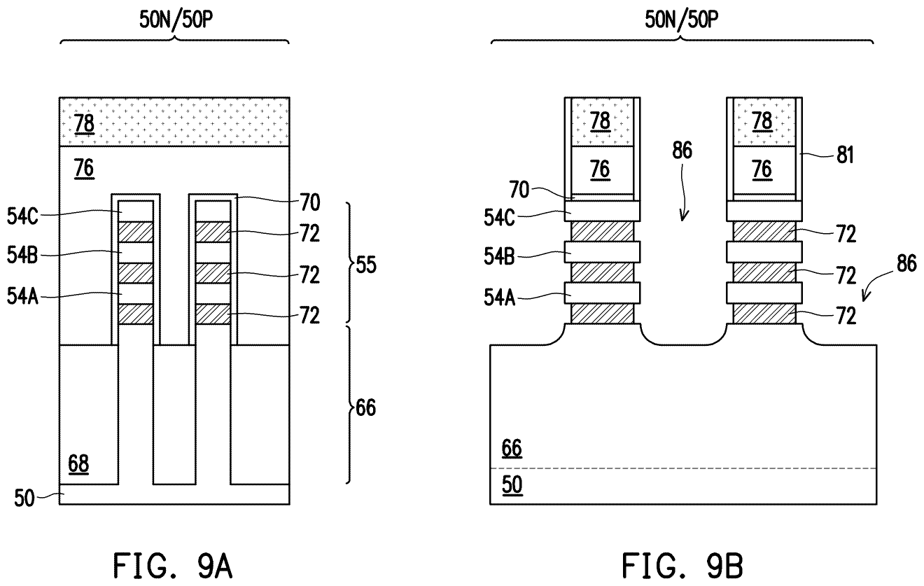

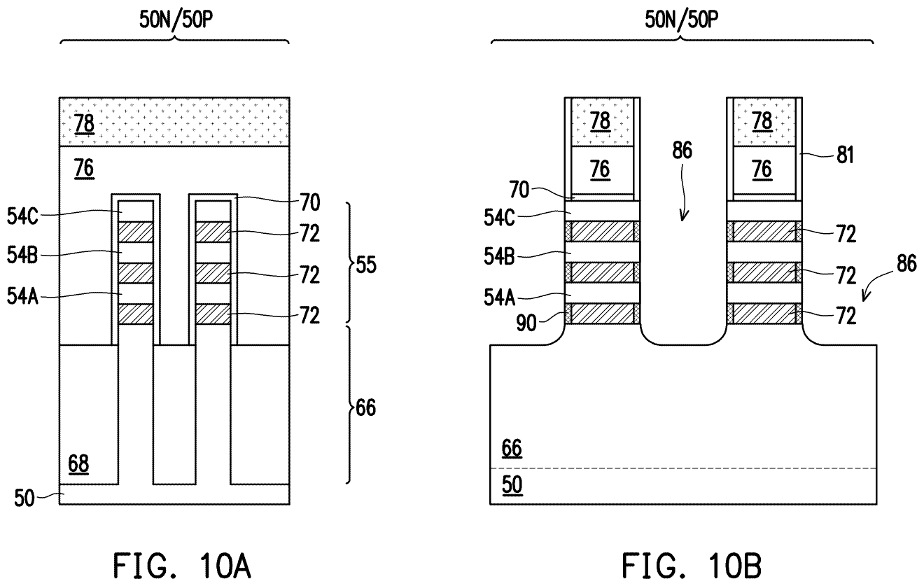

In FIGS. 8A-9B, the first nanostructures 52 are replaced with a sacrificial material 72 (also referred to as disposable oxide interposers (DOI) 72). Referring first to FIGS. 8A and 8B, replacing the first nanostructures 52 may include etching away the first nanostructures 52 using a suitable etch process, such as an isotropic etch process, that is performed through the first recesses 86. The etch process may be selective to the material of the first nanostructures 52 and remove the first nanostructures 52 without significantly removing the second nanostructures 54 or the semiconductor fins 66. In an embodiment in which the first nanostructures 52 include, e.g., SiGe, and the second nanostructures 54 include, e.g., Si or SiC, a dry etch process with tetramethylammonium hydroxide (TMAH), ammonium hydroxide (NH₄OH), or the like may be used to remove the first nanostructures 52.

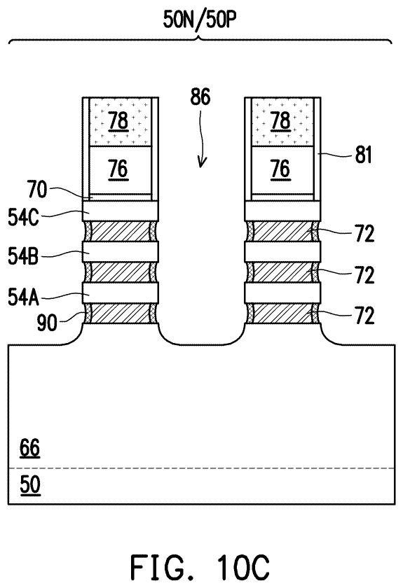

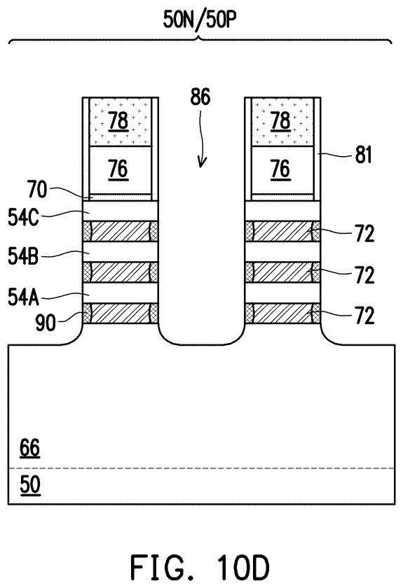

Subsequently, a sacrificial material layer 71 is deposited in the first recesses 86 and spaces where the first nanostructures 52 were removed. The sacrificial material layer 71 may be deposited by a conformal deposition process, such as CVD, ALD, or the like. The sacrificial material layer may comprise an insulating material such as silicon oxide (e.g., silicon dioxide), or the like that can be selectively etched from the second nanostructures 54. In FIGS. 9A and 9B, the sacrificial material layer 71 may then be etched to form the sacrificial material 72. The etching may be isotropic or anisotropic. For example, the sacrificial material layer may be etched by a wet etch process using diluted HF, or the like as an etchant. In some embodiments, the etching is performed until sidewalls of the sacrificial material 72 is recessed past sidewalls of the nanostructures 54. Although sidewalls of sacrificial material 72 are illustrated as being straight in FIG. 9B, the sidewalls may be concave or convex (see e.g., FIG. 10C).

Replacing the first nanostructures 52 with the sacrificial material 72 may provide advantages. For example, in subsequent source/drain formation steps, one or more high temperature processes may be performed to activate the dopants in the source/drain regions. When the material of the first nanostructures 52 (e.g., SiGe) is exposed to high temperatures, germanium intermixing and increased roughness at interfaces between the nanostructures 52 and 54 may result. Such manufacturing defects may degrade the performance of the resulting transistor devices. For example, when germanium diffuses into the second nanostructures 54, germanium residue may remain in channel regions of the resulting transistor devices, which negatively affects the performance of the channel regions. By replacing the first nanostructures 52 with an insulating material (the sacrificial material 72) prior to the high temperature processes (e.g., source/drain annealing), manufacturing defects can be reduced and device performance can be improved (e.g., increased current drive, reduced capacitance, and improved short channel effect).

In FIGS. 10A and 10B, inner spacers 90 are formed in the first recesses 86 on the sidewalls of the sacrificial material 72. The inner spacers 90 act as isolation features between subsequently formed source/drain regions and a gate structure. As will be discussed in greater detail below, source/drain regions will be formed in the first recesses 86, while the sacrificial material 72 will be replaced with corresponding gate structures. The inner spacers 90 may also be used to prevent damage to subsequently formed source/drain regions by subsequent etching processes, such as etching processes used to form gate structures.

The inner spacers 90 may be formed by depositing an inner spacer layer (not separately illustrated) over the structures illustrated in FIGS. 9A and 9B. The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the inner spacers 90. The inner spacer layer may be etched by an anisotropic etching process, such as RIE, NBE, or the like.

Although FIG. 10B illustrates outer sidewalls of the inner spacers 90 as being flush with sidewalls of the second nanostructures 54, the outer sidewalls of the inner spacers 90 may extend beyond or be recessed from sidewalls of the second nanostructures 54 (see e.g., FIG. 10C). Moreover, although the outer sidewalls of the inner spacers 90 are illustrated as being straight in FIG. 10B, the outer sidewalls of the inner spacers 90 may be concave or convex. As an example, FIG. 10C illustrates an embodiment in which sidewalls of the sacrificial material 72 are concave, outer sidewalls of the inner spacers 90 are concave, and the inner spacers 90 are recessed from sidewalls of the second nanostructures 54. Other configurations are also possible. For example, FIG. 10D illustrates an embodiment in which sidewalls of the sacrificial material 72 are concave, outer sidewalls of the inner spacers 90 are straight, and the inner spacers 90 are flush with sidewalls of the second nanostructures 54.

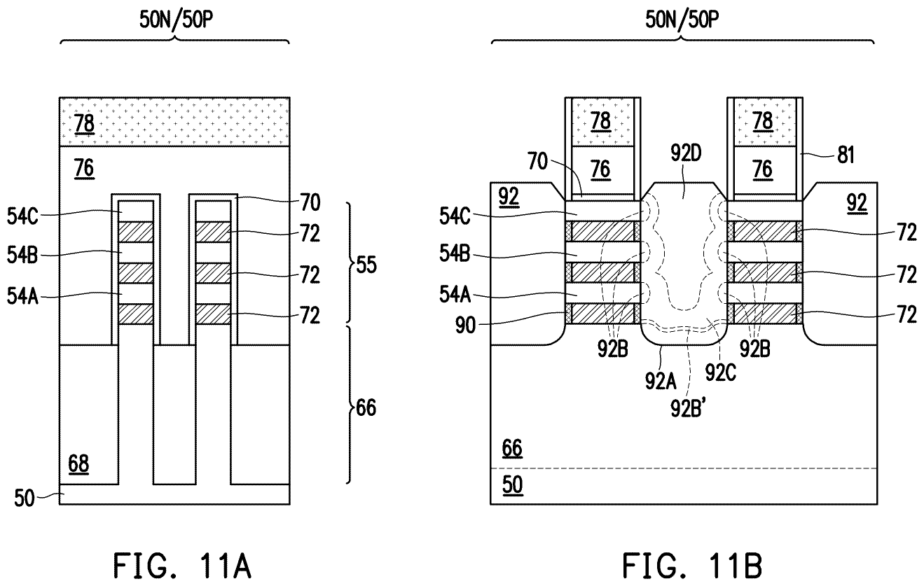

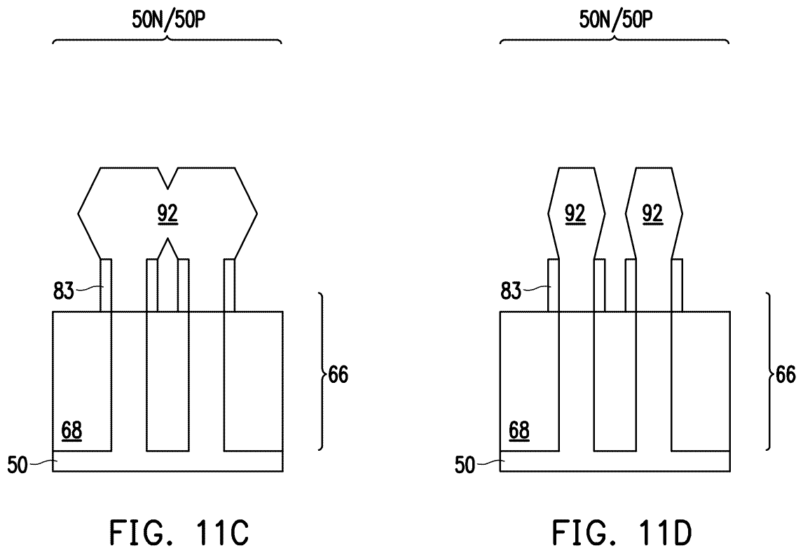

In FIGS. 11A-11D, epitaxial source/drain regions 92 are formed in the first recesses 86. In some embodiments, the source/drain regions 92 may exert stress on the second nanostructures 54 in the n-type region 50N and/or on the first nanostructures 52 in the p-type region 50P, thereby improving performance. As illustrated in FIG. 11B, the epitaxial source/drain regions 92 are formed in the first recesses 86 such that each dummy gate 76 is disposed between respective neighboring pairs of the epitaxial source/drain regions 92. In some embodiments, the gate spacers 81 are used to separate the epitaxial source/drain regions 92 from the dummy gates 76 and the inner spacers 90 are used to separate the epitaxial source/drain regions 92 from the sacrificial material 72 by an appropriate lateral distance so that the epitaxial source/drain regions 92 do not short out with subsequently formed gates of the resulting nano-FETs.

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the first recesses 86 in the n-type region 50N. The epitaxial source/drain regions 92 may include any acceptable material appropriate for n-type nano-FETs. For example, if the second nanostructures 54 are silicon, the epitaxial source/drain regions 92 in the n-type region 50N may include materials exerting a tensile strain on the second nanostructures 54, such as silicon, silicon carbide, phosphorous doped silicon carbide, silicon phosphide, or the like.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the first recesses 86 in the p-type region 50P. The epitaxial source/drain regions 92 may include any acceptable material appropriate for p-type nano-FETs. For example, if the second nanostructures 54 are silicon, the epitaxial source/drain regions 92 in the p-type region 50P may include materials exerting a compressive strain on the second nanostructures 54, such as silicon-germanium, boron doped silicon-germanium, germanium, germanium tin, or the like.

The epitaxial source/drain regions 92, the second nanostructures 54, and/or the substrate 50 may be implanted with dopants to form source/drain regions, similar to the process previously discussed for forming lightly-doped source/drain regions, followed by an anneal. The source/drain regions may have an impurity concentration of between about 1×10¹⁹ atoms/cm³ and about 1×10²¹ atoms/cm³. The n-type and/or p-type impurities for source/drain regions may be any of the impurities previously discussed. In some embodiments, the epitaxial source/drain regions 92 may be in situ doped during growth.

As a result of the epitaxy processes used to form the epitaxial source/drain regions 92 in the n-type region 50N and the p-type region 50P, upper surfaces of the epitaxial source/drain regions 92 have facets which expand laterally outward beyond sidewalls of the nanostructures 55. In some embodiments, these facets cause adjacent epitaxial source/drain regions 92 of a same nano-FET to merge as illustrated by FIG. 11C. In other embodiments, adjacent epitaxial source/drain regions 92 remain separated after the epitaxy process is completed as illustrated by FIG. 11D. In the embodiments illustrated in FIGS. 11C and 11D, the fin spacers 83 may be formed on top surfaces of the STI regions 68, thereby blocking the epitaxial growth. In some other embodiments, the fin spacers 83 may cover portions of the sidewalls of the nanostructures 55 further blocking the epitaxial growth. In some other embodiments, the spacer etch used to form the fin spacers 83 may be adjusted to remove the spacer material to allow the epitaxially grown region to extend to the surface of the STI structures 68.

The epitaxial source/drain regions 92 may comprise one or more semiconductor material layers. For example, the epitaxial source/drain regions 92 may comprise a first semiconductor material layer 92A, a second semiconductor material layer 92B, a third semiconductor material layer 92C, and a fourth semiconductor material 92D. Any number of semiconductor material layers may be used for the epitaxial source/drain regions 92.

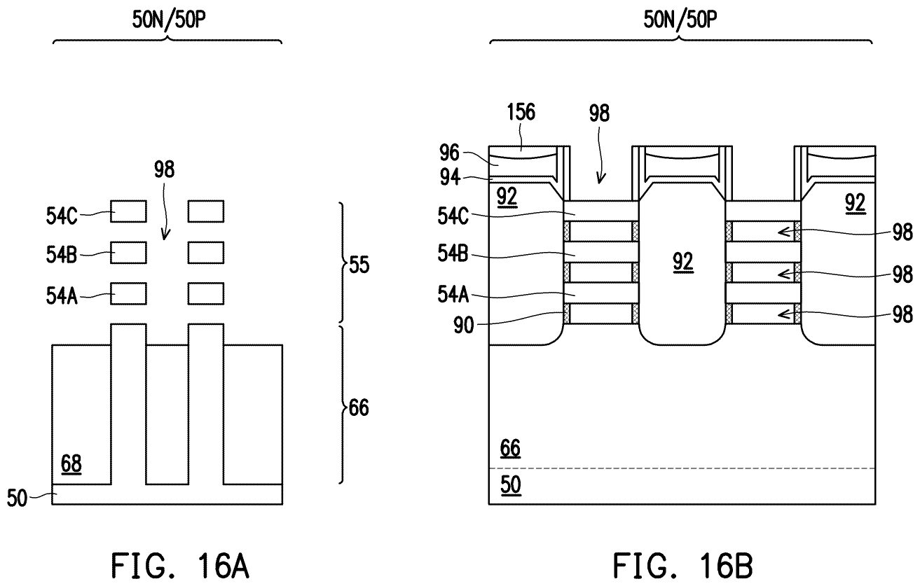

Each of the first semiconductor material layer 92A, the second semiconductor material layer 92B, the third semiconductor material layer 92C, and the fourth semiconductor material layer 92D may be formed of different semiconductor materials and may be doped to different dopant concentrations. For example, the first semiconductor material layer 92A may be a undoped or lightly doped layer that prevents or reduces diffusion of dopants from the overlying epitaxial layers (e.g., particularly the third and fourth semiconductor material layers 92C and 92D) into the underlying substrate 50. In a specific example, the first and second semiconductor material layers 92A and 92B may be silicon layers that are substantially free of germanium, and the third and fourth semiconductor material layers 92C and 92D may be silicon germanium layers. The second semiconductor material layer 92B may be high concentration, dopant layer (e.g., a high concentration boron-doped layer or the like) that is formed to increase etch selectivity along sidewalls of the second nanostructures 54 during subsequent oxide etching processes to reduce the risk of undesired etching. The oxide etching processes include processes to remove the sacrificial material 72 as described below in FIGS. 16A-16B. In embodiments in which the epitaxial source/drain regions 92 comprise four semiconductor material layers, the first semiconductor material layer 92A may be deposited, the second semiconductor material layer 92B may be formed by doping the first semiconductor material layer 92A with a suitable dopant and/or depositing the second semiconductor material layer 92B over the first semiconductor material layer 92A, the third semiconductor material layer 92C may be deposited over the second semiconductor material layer 92B, and the fourth semiconductor material layer 92D may be deposited over the third semiconductor material layer 92C. Other source/drain configurations are also possible in other embodiments.

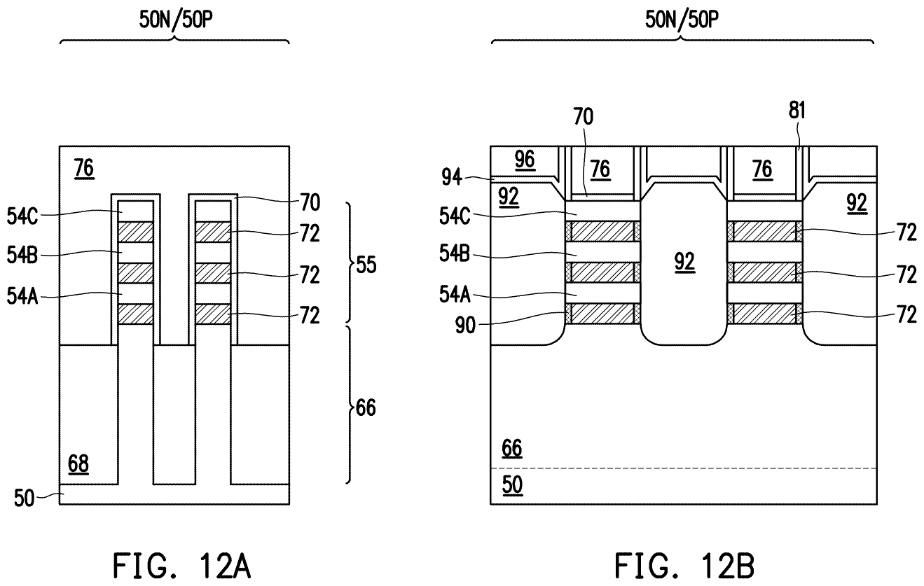

In FIGS. 12A and 12B, a first interlayer dielectric (ILD) layer 96 is deposited over the structure illustrated in FIGS. 11A and 11B, respectively. The first ILD layer 96 may be formed of a dielectric material, and may be deposited by any suitable method, such as CVD, plasma-enhanced CVD (PECVD), or FCVD. Dielectric materials may include silicon oxide, phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD layer 96 and the epitaxial source/drain regions 92, the masks 78, and the gate spacers 81. The CESL 94 may comprise a dielectric material, such as, silicon nitride, silicon oxide, silicon oxynitride, or the like, having a different etch rate than the material of the overlying first ILD layer 96.

After the first ILD layer 96 is deposited, a planarization process, such as a CMP, may be performed to level the top surface of the first ILD layer 96 with the top surfaces of the dummy gates 76 (as shown) or the masks 78. The planarization process may also remove the masks 78 on the dummy gates 76, and portions of the gate spacers 81 along sidewalls of the masks 78. After the planarization process, top surfaces of the dummy gates 76, the gate spacers 81, and the first ILD layer 96 are level within process variations. Accordingly, the top surfaces of the dummy gates 76 are exposed through the first ILD layer 96. In some embodiments, the masks 78 may remain, in which case the planarization process levels the top surface of the first ILD layer 96 with top surface of the masks 78 and the gate spacers 81.

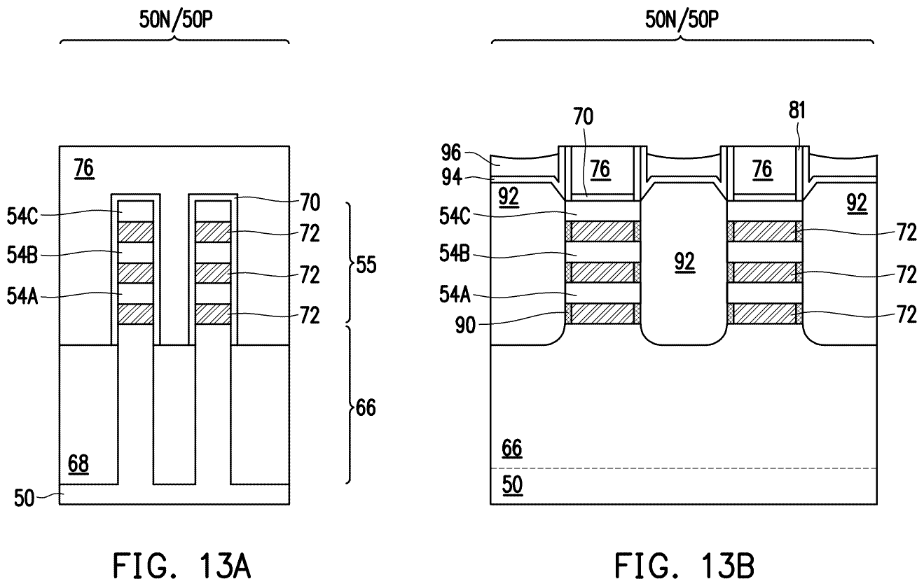

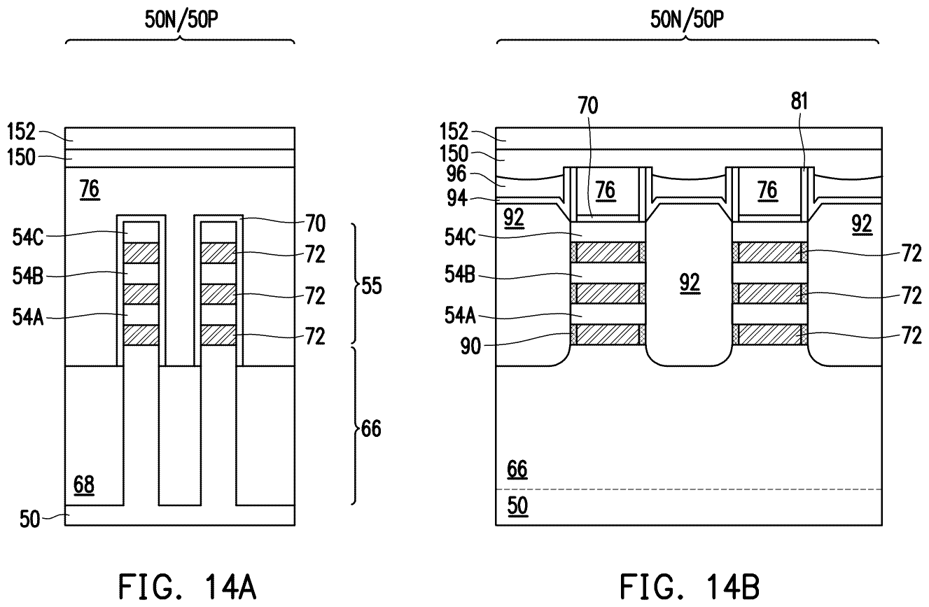

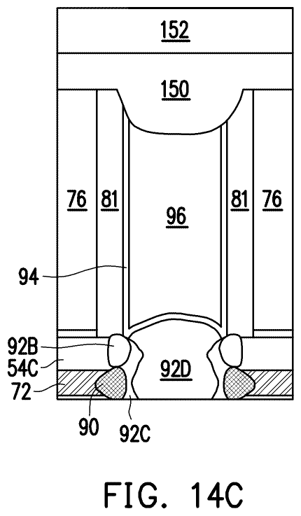

In FIGS. 13A and 13B, the first ILD layer 96 may be recessed below top surfaces of the dummy gates 76 and the gate spacers 81. In some embodiments, the first ILD layer 96 may further be recessed such that the CESL 94 extends above a top surface of the first ILD layer 96. Recessing the first ILD layer 96 may be performed using any suitable etch back process that selectively etches the first ILD layer 96 compared to the dummy gates 76. The etching may be anisotropic. This anisotropic etching allows for precise control of the recess depth while maintaining the lateral dimensions of the first ILD layer 96. Suitable etching techniques may include reactive ion etching (RIE) or plasma etching, using etchants that selectively react with the ILD material without significantly etching the dummy gates 76, the gate spacers 81, and/or the CESL 94. In some embodiments, recessing the first ILD layer 96 may also recess the CESL 94 and/or partially etch the gate spacers 81 (see e.g., FIG. 14C). The degree to which the CESL 94/gate spacers 81 is etched may vary depending on the specific materials of the first ILD layer 96, the CESL 94, and the gate spacers 81.

In FIGS. 14A and 14B, the hard mask material layer 150 is deposited over the first ILD layer 96, the CESL 94, the gate spacers 81, and the dummy gates 76. The hard mask material layer 150 may be deposited onto the recessed first ILD layer 96 into spaces between the dummy gates 76. The hard mask material layer 150 may be formed of a dielectric material, and may be deposited by any suitable method, such as CVD, plasma-enhanced CVD (PECVD), or FCVD. Suitable dielectric materials for the hard mask material layer 150 include silicon nitride, silicon oxynitride, or the like. The hard mask material layer 150 has etch selectivity relative to the first ILD layer 96 and the sacrificial material 72. For example, the hard mask material layer 150 may have a lower etch rate during an oxide etching process than the first ILD layer 96 and the sacrificial material 72. The hard mask material layer 150 may be deposited to contact sidewalls of the CESL 94.

An optional buffer layer 152 may be deposited over the hard mask material layer 150. The buffer layer 152 may be made of oxide material, such as silicon oxide, or the like. The buffer layer 152 may reduce pattern density across the device for the subsequent planarization processes. By introducing this layer, the overall topography of the structure is modified, creating a more uniform surface for the planarization process. The buffer layer 152 can be deposited using various techniques such as CVD, PECVD, PVD, or the like.

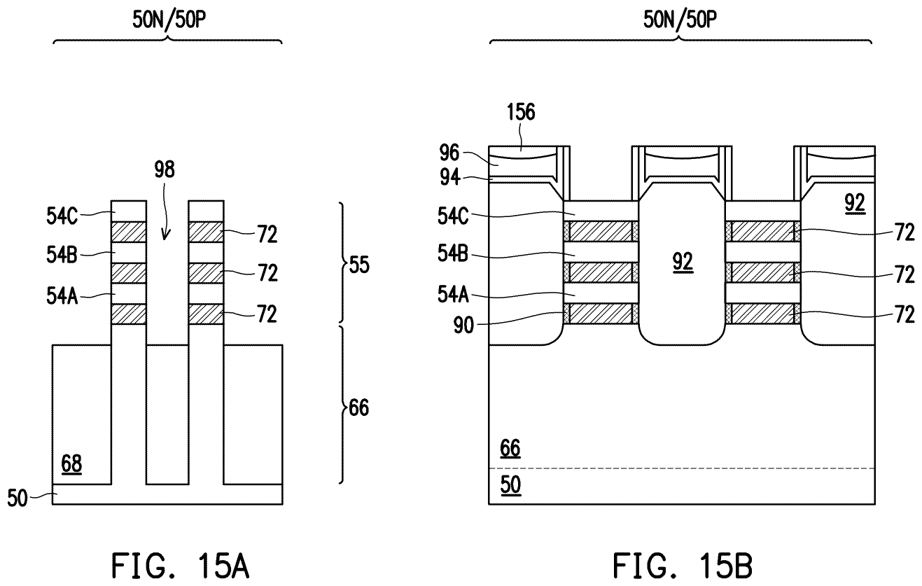

In FIGS. 15A and 15B, a planarization process, such as a CMP, may be performed to level the top surface of the hard mask material layer 150 with the top surfaces of the dummy gates 76 and the gate spacers 81 within process variations. After the planarization process, the hard mask material layer 150 may be referred to as hard masks 156. The planarization process may remove the buffer layer 152 (if present). Although the buffer layer 152 may be included to prove the planarity of a top surface of the hard masks 156, limitations in the planarization process may still result in slight surface variations on the top surface of the hard masks 156. For example, FIG. 15C illustrates an embodiment where the top surfaces of the hard masks 156 include one or more divots. However, these slight deviations in the topography of the hard masks 156 may still remain within tolerance of the device manufacturing process.

In FIGS. 15A and 15B, after performing the planarization process of the hard mask material layer 150, the dummy gates 76 are removed in one or more etching steps, so that second recesses 98 are formed. Portions of the dummy gate dielectrics 70 in the second recesses 98 may also be removed. In some embodiments, the dummy gates 76 and the dummy gate dielectrics 70 are removed by an anisotropic dry etch process. For example, the etching process may include a dry etch process using reaction gas(es) that selectively etch the dummy gates 76 at a faster rate than the hard masks 156, the first ILD layer 96, or the gate spacers 81. Each second recess 98 exposes and/or overlies portions of nanostructures 55, which act as channel regions in subsequently completed nano-FETs. Portions of the nanostructures 55 which act as the channel regions are disposed between neighboring pairs of the epitaxial source/drain regions 92. During the removal, the dummy gate dielectrics 70 may be used as etch stop layers when the dummy gates 76 are etched. The dummy gate dielectrics 70 may then be removed after the removal of the dummy gates 76.

In FIGS. 16A and 16B, the sacrificial material 72 is removed, extending the second recesses 98. Removing the sacrificial material 72 may include performing an isotropic etching process such as wet etching or the like using etchants which are selective to the materials of the sacrificial material 72, while the second nanostructures 54 remain relatively unetched as compared to the sacrificial material 72. The sacrificial material 72 may be completely removed, or a residue of the sacrificial material 72 may remain on sidewalls of the inner spacers in the second recesses 98. Removing the sacrificial material 72 may include an oxide etch process, such as dry etch process, a wet etch process using dHF as an etchant, or the like.

In some embodiments, the STI regions 68 may be etched while removing the sacrificial material 72, but the total amount of loss in the STI regions 68 may be reduced by controlling etching parameters (e.g., timing) while removing the sacrificial material 72. In other embodiments, the STI regions 68 may include a hard mask (not separately illustrated) at a top surface to protect the underlying STI regions 68 from etching while patterning and removing the sacrificial material 72. In such embodiments, the hard mask may include a nitride layer.

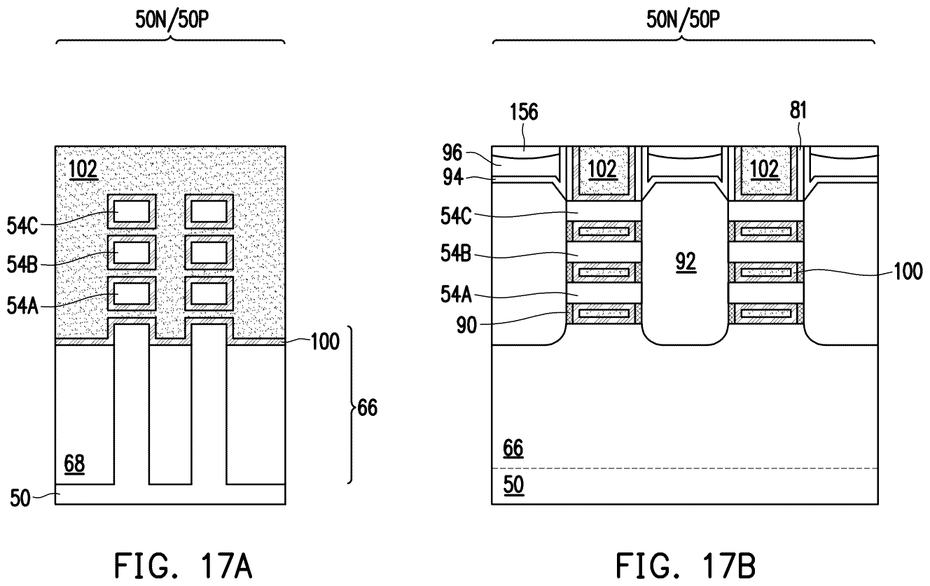

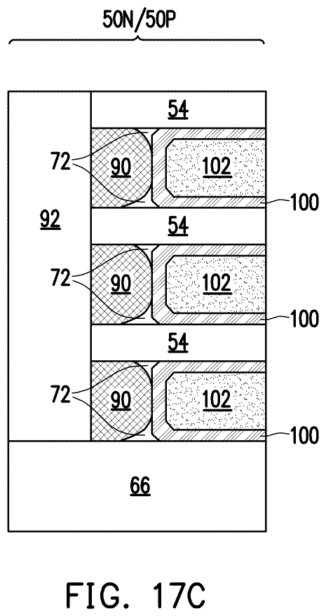

In FIGS. 17A-17C, gate dielectric layers 100 and gate electrodes 102 are formed for replacement gates. The gate dielectric layers 100 are deposited conformally in the second recesses 98. The gate dielectric layers 100 may be formed on top surfaces and sidewalls of the substrate 50 and on top surfaces, sidewalls, and bottom surfaces of the second nanostructures 54. The gate dielectric layers 100 may also be deposited on top surfaces of the first ILD layer 96, the CESL 94, the gate spacers 81, and the STI regions 68.

In accordance with some embodiments, the gate dielectric layers 100 comprise one or more dielectric layers, such as an oxide, a metal oxide, the like, or combinations thereof. In some embodiments, the gate dielectrics may comprise a silicon oxide layer and a metal oxide layer over the silicon oxide layer. In some embodiments, the gate dielectric layers 100 include a high-k dielectric material, and in these embodiments, the gate dielectric layers 100 may have a k value greater than about 7.0, and may include a metal oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, and the like.

The gate electrodes 102 are deposited over the gate dielectric layers 100, respectively, and fill the remaining portions of the second recesses 98. The gate electrodes 102 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 102 are illustrated in FIGS. 17A-17C, the gate electrodes 102 may comprise any number of liner layers, any number of work function tuning layers, and a fill material. Any combination of the layers which make up the gate electrodes 102 may be deposited in the n-type region 50N between adjacent ones of the second nanostructures 54 and between the second nanostructure 54A and the substrate 50, and may be deposited in the p-type region 50P between adjacent ones of the first nanostructures 52.

The formation of the gate dielectric layers 100 in the n-type region 50N and the p-type region 50P may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the second recesses 98, a planarization process, such as a CMP, may be performed to remove the excess portions of the gate dielectric layers 100 and the material of the gate electrodes 102, which excess portions are over the top surface of the first ILD layer 96. The remaining portions of material of the gate electrodes 102 and the gate dielectric layers 100 thus form replacement gate structures of the resulting nano-FETs. The gate electrodes 102 and the gate dielectric layers 100 may be collectively referred to as “gate structures.”

FIG. 17C illustrates a detailed view of various elements of FIG. 17B, including the epitaxial source/drain regions 92, the gate dielectric layers 100, the gate electrodes 102, the second nanostructures 54, and the inner spacers 90. In some embodiments, as illustrated by FIG. 17C, a residue of the sacrificial material 72 may remain on the inner spacers 90, such as between the inner spacers 90 and the gate dielectric layers 100/gate electrodes 102. The sacrificial material 72 may not be fully removed, and the gate dielectric layers 100 may be formed on the remaining sacrificial material 72. Because the sacrificial material 72 is an insulating material (e.g., silicon oxide), the remaining residue may not significantly impact the electrical performance of the resulting device.

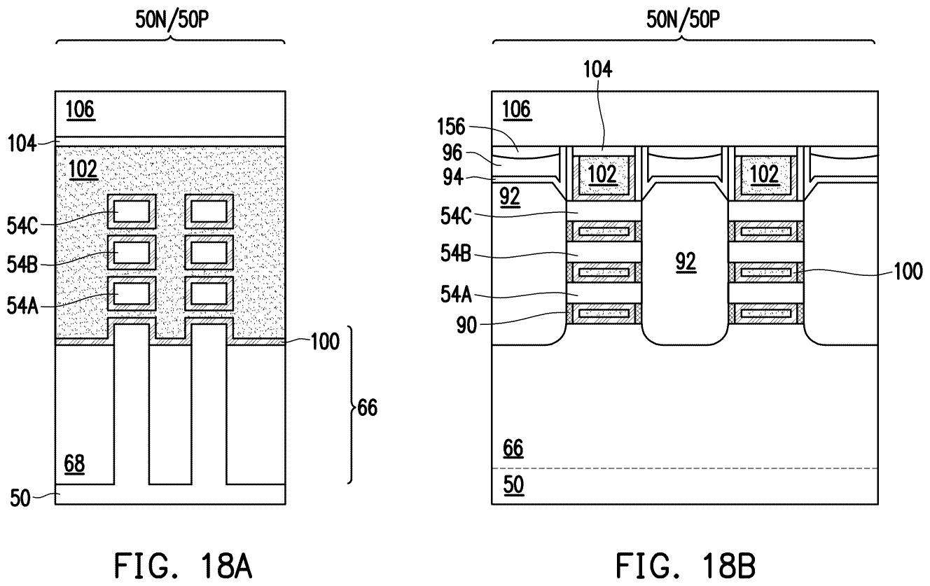

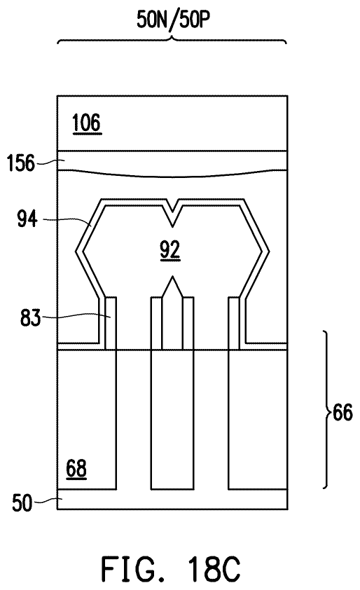

In FIGS. 18A-18C, the gate structure (including the gate dielectric layers 100 and the corresponding overlying gate electrodes 102) is recessed, so that a recess is formed directly over the gate structure and between opposing portions of gate spacers 81. A gate mask 104 comprising one or more layers of dielectric material, such as silicon nitride, silicon oxynitride, or the like, is filled in the recess, followed by a planarization process to remove excess portions of the dielectric material extending over the first ILD layer 96. Subsequently formed gate contacts (such as the gate contacts 114, discussed below with respect to FIGS. 18A-18C) penetrate through the gate mask 104 to contact the top surface of the recessed gate electrodes 102.

As further illustrated by FIGS. 18A-18C, a second ILD 106 is deposited over the first ILD layer 96 and over the gate mask 104. In some embodiments, the second ILD 106 is a flowable film formed by FCVD. In some embodiments, the second ILD 106 is formed of a dielectric material such as PSG, BSG, BPSG, USG, or the like, and may be deposited by any suitable method, such as CVD, PECVD, or the like.

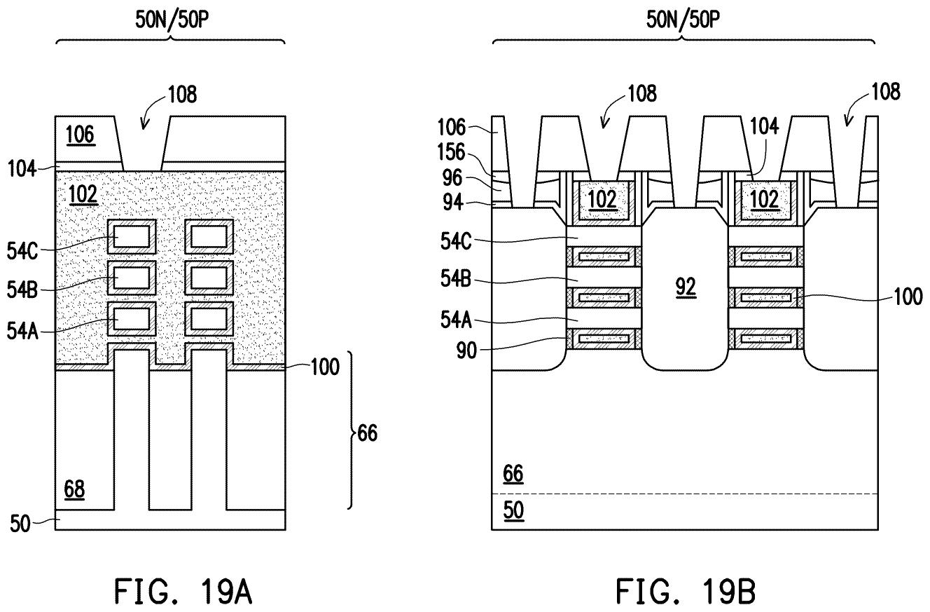

In FIGS. 19A-19C, the second ILD 106, the first ILD layer 96, the CESL 94, and the gate masks 104 are etched to form contact openings 108 exposing surfaces of the epitaxial source/drain regions 92 and/or the gate structure. The contact openings 108 may be formed by etching using an anisotropic etching process, such as RIE, NBE, or the like. In some embodiments, the contact openings 108 may be etched through the second ILD 106 and the first ILD layer 96 using a first etching process; may be etched through the gate masks 104 using a second etching process; and may then be etched through the CESL 94 using a third etching process. A mask, such as a photoresist, may be formed and patterned over the second ILD 106 to mask portions of the second ILD 106 from the first etching process and the second etching process. In some embodiments, the etching process may over-etch, and therefore, the contact openings 108 extend into the epitaxial source/drain regions 92 and/or the gate structure, and a bottom of the contact openings 108 may be level with (e.g., at a same level, or having a same distance from the substrate), or lower than (e.g., closer to the substrate) the epitaxial source/drain regions 92 and/or the gate structure. Although FIG. 19B illustrate the contact openings 108 as exposing the epitaxial source/drain regions 92 and the gate structure in a same cross section, in various embodiments, the epitaxial source/drain regions 92 and the gate structure may be exposed in different cross-sections, thereby reducing the risk of shorting subsequently formed contacts.

After the contact openings 108 are formed, silicide regions 110 are formed over the epitaxial source/drain regions 92. In some embodiments, the silicide regions 110 are formed by first depositing a metal (not shown) capable of reacting with the semiconductor materials of the underlying epitaxial source/drain regions 92 (e.g., silicon, silicon germanium, germanium) to form silicide or germanide regions. For example, metals such as nickel, cobalt, titanium, tantalum, platinum, tungsten, other noble metals, other refractory metals, rare earth metals or their alloys, may be used. The metal may be deposited over the exposed portions of the epitaxial source/drain regions 92. A thermal annealing process may then be utilized to form the silicide regions 110. The un-reacted portions of the deposited metal are then removed, e.g., by an etching process. Although silicide regions 110 are referred to as silicide regions, silicide regions 110 may also be germanide regions, or silicon germanide regions (e.g., regions comprising silicide and germanide). In an embodiment, the silicide region 110 comprises TiSi, and has a thickness in a range between about 2 nm and about 10 nm.

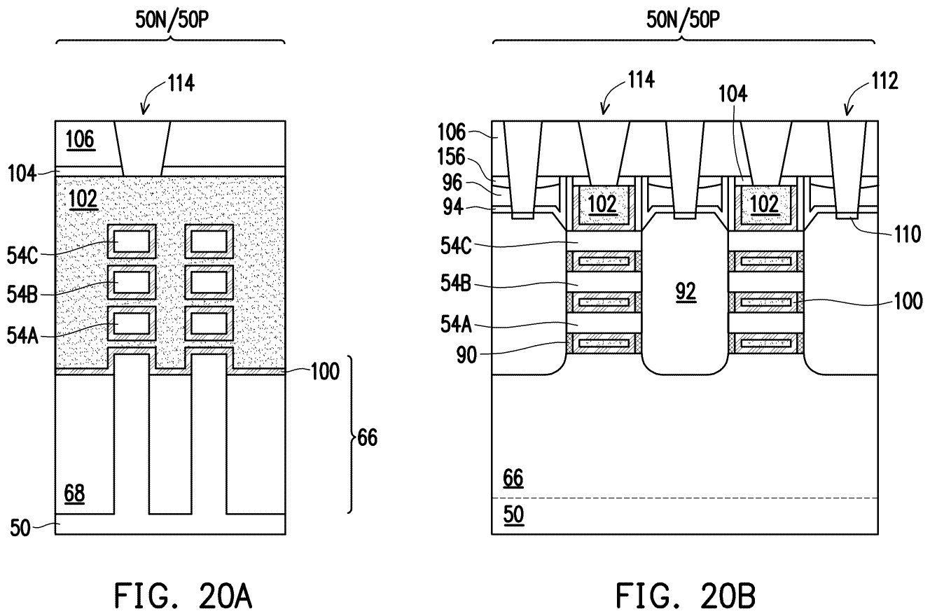

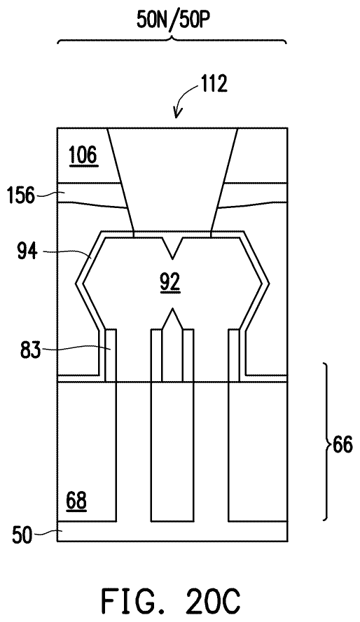

Next, in FIGS. 20A-20C, bottom tier source/drain contact structures 112 (may also be referred to as source/drain contact plugs) and gate contacts 114 (may also be referred to as gate contact plugs) are formed in the contact openings 108. The bottom tier source/drain contact structures 112 and the gate contacts 114 may each comprise one or more layers, such as barrier layers, diffusion layers, and fill materials. In some embodiments, the bottom tier source/drain contact structures 112 each includes a barrier layer and a conductive material, and are electrically coupled to the underlying conductive feature (e.g., the silicide region 110 in the illustrated embodiment). The gate contacts 114 each includes a barrier layer and a conductive material, and are electrically coupled to the underlying conductive features (e.g., the gate electrodes 102). The barrier layer of the bottom tier source/drain contact structures 112 may include titanium, titanium nitride, tantalum, tantalum nitride, or the like. The conductive material of the bottom tier source/drain contact structures 112 may be copper, a copper alloy, silver, gold, tungsten, cobalt, aluminum, nickel, or the like. A planarization process, such as a CMP, may be performed to remove excess material from a surface of the second ILD 106. The bottom tier source/drain contact structures 112 and the and gate contacts 114 have top surfaces substantially level with the top surface of the second ILD 106.

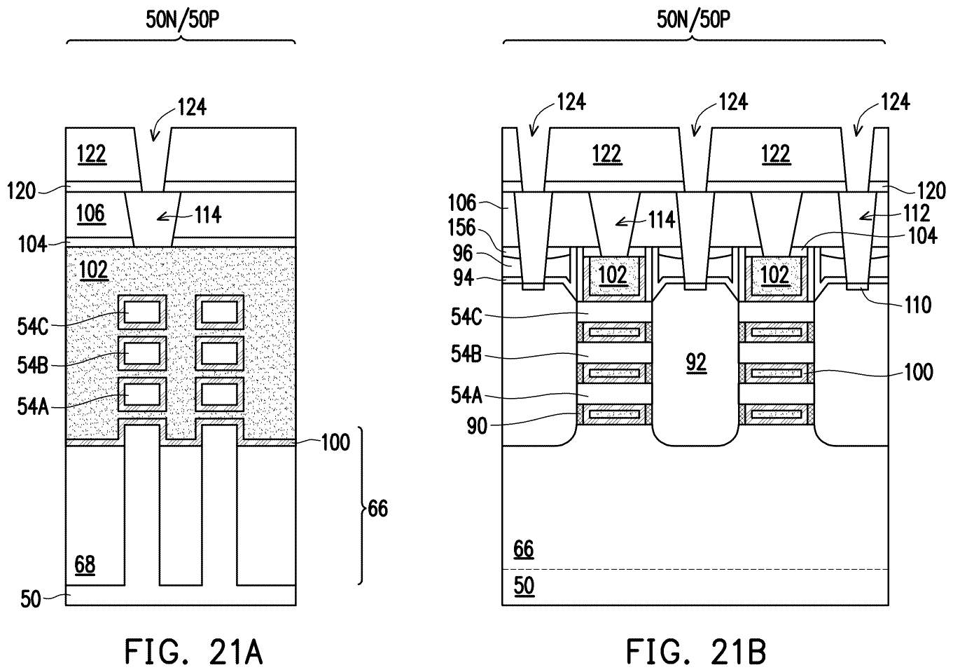

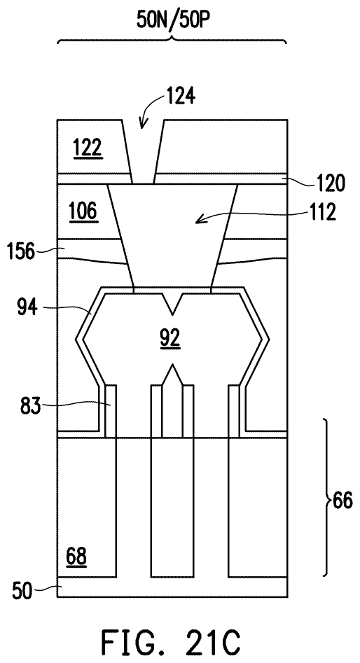

In FIGS. 21A-21C, a CESL 120 is formed over the resulted structure illustrated in FIGS. 20A-20C. The CESL 120 is deposited on the second ILD 106, the bottom tier source/drain contact structures 112, and the gate contacts 114. The CESL 120 may include a dielectric material, such as, silicon nitride, silicon oxide, silicon oxynitride, or the like, having a different etch rate than the material of the overlying second ILD layer 106. Then, a third interlayer dielectric (ILD) layer 122 is deposited over the CESL 120. The third ILD layer 122 may be formed of a dielectric material, and may be deposited by any suitable method, such as CVD, plasma-enhanced CVD (PECVD), or FCVD. Dielectric materials for forming the third ILD layer 122 may include silicon oxide, phospho-silicate glass (PSG), boro-silicate glass (BSG), boron-doped phospho-silicate glass (BPSG), undoped silicate glass (USG), or the like. Other insulation materials formed by any acceptable process may be used.

After the third ILD layer 122 is deposited, the third ILD layer 122 and the CESL 120 are etched to form contact openings 124 exposing top surfaces of the bottom tier source/drain contact structures 112 and the gate contacts 114. The contact openings 124 may be formed by etching using an anisotropic etching process, such as RIE, NBE, or the like. In some embodiments, the contact openings 124 may be etched through the third ILD layer 122 and the CESL 120 through an etching process. A mask, such as a photoresist, may be formed and patterned over the third ILD 122 to mask portions of the third ILD 122 during the above-mentioned etching process of the third ILD layer 122 and the CESL 120. In some embodiments, the etching process may over-etch, and therefore, the contact openings 124 slightly extend into the bottom tier source/drain contact structures 112 and/or the gate contacts 114, and a bottom of the contact openings 124 may be level with or slightly lower than the top surface of the bottom tier source/drain contact structures 112 and/or the gate contacts 114. After forming the contact openings 124 in the third ILD layer 122 and the CESL 120, the photoresist used in the etching process of the third ILD layer 122 and the CESL 120 is removed from the top surface of the third ILD layer 122.

Although FIG. 21B illustrates the contact openings 124 as exposing the bottom tier source/drain contact structures 112 and the gate contacts 114 in a same cross section, in various embodiments, the bottom tier source/drain contact structures 112 and the gate contacts 114 may be exposed in different cross-sections, thereby reducing the risk of shorting subsequently formed contacts.

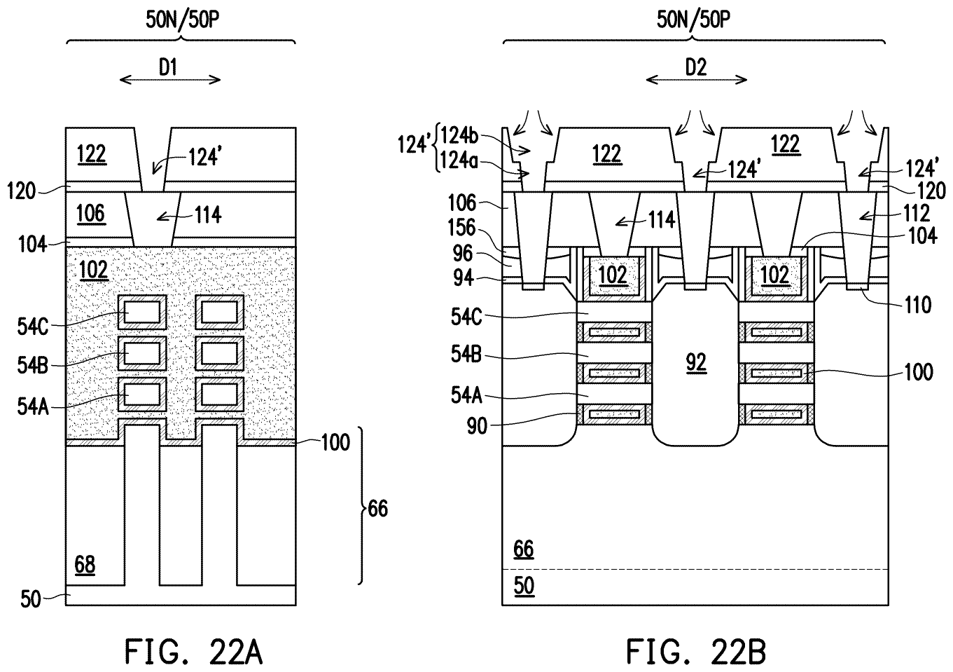

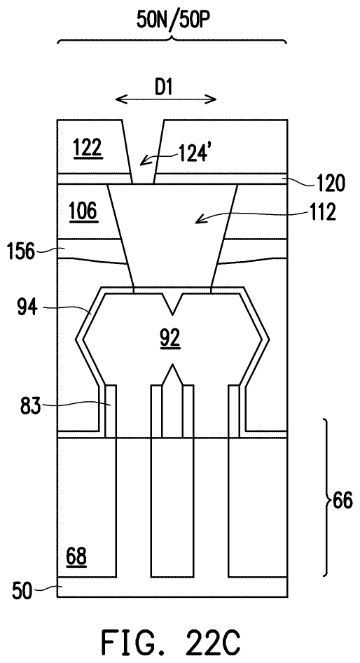

In FIGS. 22A-22C, the profile of the contact openings 124 are re-shaped such that contact openings 124′ with re-shaped tapered or curved sidewalls are formed in the third ILD layer 122 and the CESL 120. The re-shaped contact openings 124′ has step sidewalls. The re-shaped contact openings 124′ each includes a lower portion 124a and an upper portion 124b located over the lower portion 124a. In some embodiments, the contact openings 124 is re-shaped through an anisotropic etch process. As illustrated in FIGS. 21B and 22B, the anisotropic etch process includes using a plasma controlled by electric field to exclusively expand the first lateral dimension (i.e., the width) of upper portions of the contact openings 124 (shown in FIG. 21B) in the second direction D2 (i.e., the widthwise direction of the gate electrodes 102), and accordingly, the contact openings 124′ including expanded upper portions 124b (shown in FIG. 22B) are formed in third ILD layer 122 and the CESL 120. The second direction D2 is perpendicular to the first direction D1. The plasma may laterally etch or remove portions of the third ILD layer 122 through proper control of electric field. As illustrated in FIGS. 22A and 22C, the second lateral dimension (i.e., the width) of the upper portions 124b of the contact openings 124′ in the first direction D1 (i.e., the lengthwise direction of the gate electrodes 102) remains after performing the anisotropic etch process.

As illustrated in FIG. 22B, in the second direction D2 (i.e., the widthwise direction of the gate electrodes 102), the top width of the upper portions 124b of the contact openings 124′ is greater than the bottom width of the upper portions 124b of the contact openings 124′, and each of the upper portions 124b of the contact openings 124′ has tapered sidewalls, respectively. In the second direction D2 (i.e., the widthwise direction of the gate electrodes 102), the top width of the lower portions 124a of the contact openings 124′ is greater than the bottom width of the lower portions 124a of the contact openings 124′, and each of the lower portions 124a of the contact openings 124′ has tapered sidewalls, respectively. In some embodiments, the above-mentioned tapered sidewalls of the upper portions 124b and the above-mentioned tapered sidewalls of the lower portions 124a are substantially the same in slope. In some other embodiments, the above-mentioned tapered sidewalls of the upper portions 124b and the above-mentioned tapered sidewalls of the lower portions 124a are different in slope. Furthermore, as illustrate in FIG. 22B, the bottom width of the upper portions 124b of the contact openings 124′ is greater than the top width of the lower portions 124a of the contact openings 124′. In some alternative embodiments, the bottom width of the upper portions 124b of the contact openings 124′ substantially equals to the top width of the lower portions 124a of the contact openings 124′.

After performing the above-mentioned anisotropic etch process, the re-shaped contact openings 124′ each includes a lower portion 124a and an upper portion 124b, wherein the upper portions 124b have a first top width in the first direction D1 (i.e., the lengthwise direction of the gate electrodes 102), the upper portions further have a second top width in the second direction D2 (i.e., the widthwise direction of the gate electrodes 102), and the second top width of the upper portions 124b is greater than the first top width of the upper portions 124b. Furthermore, the lower portions 124a has a first bottom width in the first direction D1 (i.e., the lengthwise direction of the gate electrodes 102), and the lower portions have a second bottom width in the second direction D2 (i.e., the widthwise direction of the gate electrodes 102). For example, the ratio of the second top width of the upper portions 124b to the first top width of the upper portions 124b is greater than 1.1, and the ratio of the second bottom width of the lower portions 124a to the first bottom width of the lower portions 124a ranges from about 0.9 to about 1.1.

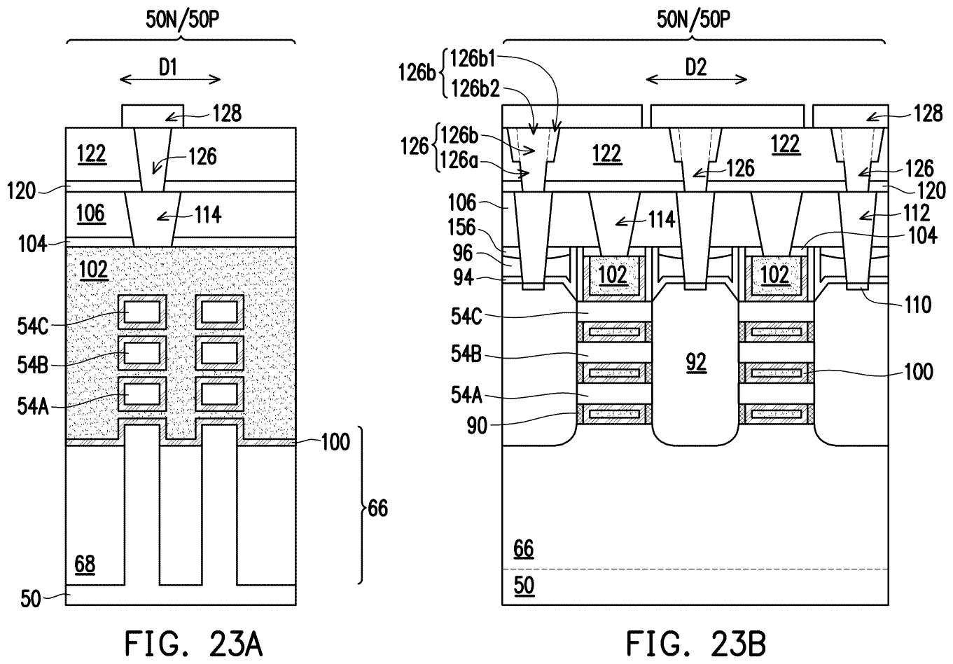

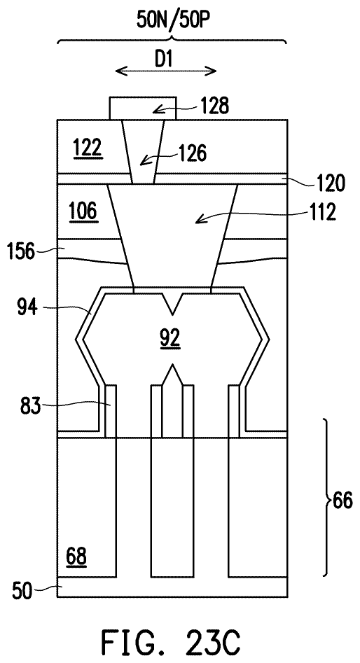

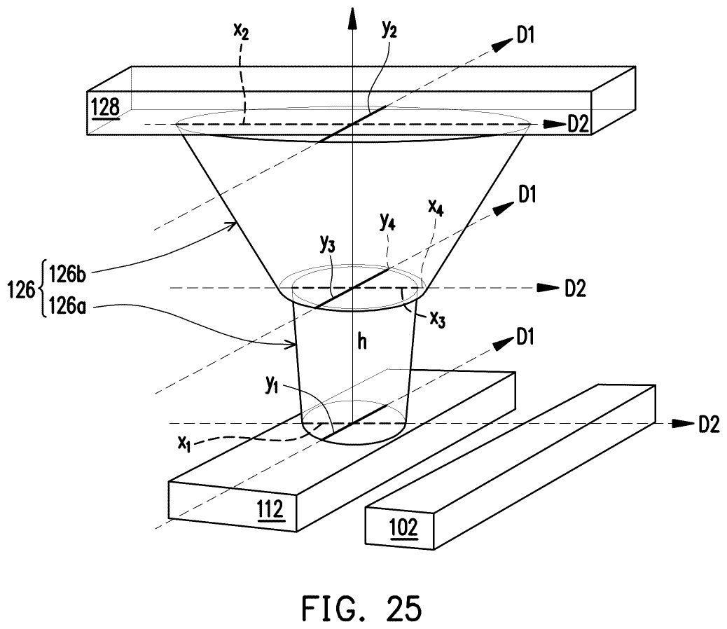

In FIGS. 23A-23C and FIG. 25, after forming the contact opening 124′, upper tier source/drain contact structures 126 are formed in the contact opening 124′, wherein the upper tier source/drain contact structures 126 are electrically connected to the underlying source/drain regions 92 through the bottom tier source/drain contact structures 112. The upper tier source/drain contact structures 126 each includes a lower part 126a and an upper part 126b. The lower part 126a is electrically connected to the source/drain regions 92 through the bottom tier source/drain contact structures 112, the upper part 126b is disposed on the lower part 126a, wherein the upper part 126b has a first top width y₂ in the first direction D1 (i.e., the lengthwise direction of the gate electrodes 102), the upper part 126b has a second top width x₂ in a second direction D2 (i.e., the widthwise direction of the gate electrodes 102) different from the first direction D1, and the second top width y₂ of the upper part 126b is greater than the first top width y₂ of the upper part 126b. The height h of the lower part s 126a may be greater than the thickness of the CESL120. For example, the height h of the lower part s 126a ranges from about 2 nanometers to about 10 nanometers. In some embodiments, the upper parts 126a are in contact with the third ILD layer 122, and the lower parts 126a is in contact with the third ILD layer 122 and the CESL120 at the same time.

Next, in FIGS. 23A-23C, the upper tier source/drain contact structures 126 may each comprise one or more layers, such as barrier layers, diffusion layers, and fill materials. In some embodiments, the upper tier source/drain contact structures 126 each includes a barrier layer and a conductive material, and are electrically coupled to the underlying conductive features (e.g., the bottom tier source/drain contact structures 112 in the illustrated embodiment). The barrier layer of the upper tier source/drain contact structures 126 may include titanium, titanium nitride, tantalum, tantalum nitride, or the like. The conductive material of the upper tier source/drain contact structures 126 may be copper, a copper alloy, silver, gold, tungsten, cobalt, aluminum, nickel, or the like. A planarization process, such as a CMP, may be performed to remove excess material from a surface of the third ILD 122. The upper tier source/drain contact structures 126 may have top surfaces substantially level with the top surface of the third ILD 122.

As illustrated in FIG. 23B, the upper part 126b may include a via part 126b1 and a pair of lateral extending parts 126b2. The pair of lateral extending parts 126b2 are located at two opposite sides of the via part 126b1. Each of the pair of lateral extending parts 126b2 laterally extend from the sidewall of the via part 126b1, and the extending directions of the lateral extending parts 126b2 are opposite to each other. In some embodiments, the pair of lateral extending parts 126b2 are identical in geometry, dimension, and/or material. As illustrated in FIG. 23B, the pair of lateral extending parts 126b2 are symmetrically arranged with respect to the via part 126b1.

Interconnect wirings 128 are formed on the third LID layer 122 to cover the upper tier source/drain contact structures 126, wherein the interconnect wirings 128 land on the upper parts 126b of the upper tier source/drain contact structures 126, and the upper part 126b is in contact with the overlying interconnect wiring 128. The interconnect wirings 128 may each comprise one or more layers. The interconnect wirings 128 may each include a seed layer and a plated conductive layer formed on the seed layer. The seed layer of the interconnect wirings 128 may include titanium, copper, or the like. The conductive material of the interconnect wirings 128 may be copper, a copper alloy, silver, gold, tungsten, cobalt, aluminum, nickel, or the like.

In the second direction D2 (i.e., the widthwise direction of the gate electrodes 102 or the lengthwise direction of the interconnect wirings 128), the top width x₂ of the upper parts 126b of the upper tier source/drain contact structures 126 is greater than the bottom width x₄ of the upper parts 126b of the upper tier source/drain contact structures 126, and each of the upper parts 126b of the upper tier source/drain contact structures 126 has tapered sidewalls, respectively. In the second direction D2 (i.e., the widthwise direction of the gate electrodes 102 or the lengthwise direction of the interconnect wirings 128), the top width x₃ of the lower parts 126a of the upper tier source/drain contact structures 126 is greater than the bottom width x₁ of the lower parts 126a of the upper tier source/drain contact structures 126, and each of the lower parts 126a of the upper tier source/drain contact structures 126 has tapered sidewalls, respectively. Furthermore, in the second direction D2 (i.e., the widthwise direction of the gate electrodes 102 or the lengthwise direction of the interconnect wirings 128), the bottom width x₄ of the upper parts 126b of the upper tier source/drain contact structures 126 is greater than the top width x₃ of the lower parts 126a of the upper tier source/drain contact structures 126.

In some embodiments, the lower parts 126a each has a first bottom width y₁ in the widthwise direction (D1) of the overlying interconnect wiring 128, the lower parts 126a each has a second bottom width x₁ in the lengthwise direction (D2) of the overlying interconnect wiring 128, and the ratio (x₁/y₁) of the second bottom width of the lower parts 126a to the first bottom width of the lower parts 126a may range from about 0.9 to about 1.1. The ratio (x₂/y₂) of the second top width of the upper parts 126b to the first top width of the upper parts 126a is greater than 1.1. Furthermore, the first top width y₂ of the upper parts 126b is greater than the first bottom width y₁ of the lower parts 126a, and the second top width x₂ of the upper parts 126 is greater than the second bottom width x₁ of the lower parts 126a. In some embodiments, the lengthwise direction of the gate electrodes 102 is different from the lengthwise direction of the overlying interconnect wiring 128. For example, the lengthwise direction of the gate electrodes 102 is perpendicular to the lengthwise direction of the overlying interconnect wiring 128.

The above-mentioned design of the upper tier source/drain contact structures 126 (i.e. the lateral extending parts 126b2 of the upper parts 126b) may reduce bulk resistance of the upper tier source/drain contact structures 126. The expanded upper parts 126b of the upper tier source/drain contact structures 126 may reduce interface resistance between the upper tier source/drain contact structures 126 and overlying interconnect wirings 128 without modifying the layout area of the overlying interconnect wirings 128. Furthermore, the above-mentioned design of the upper tier source/drain contact structures 126 (i.e. the lower parts 126a) may prevent the leakage issue between the upper tier source/drain contact structures 126 and the gate electrodes 102, and accordingly, the reliability and performance of the nano-FETs can be enhanced.

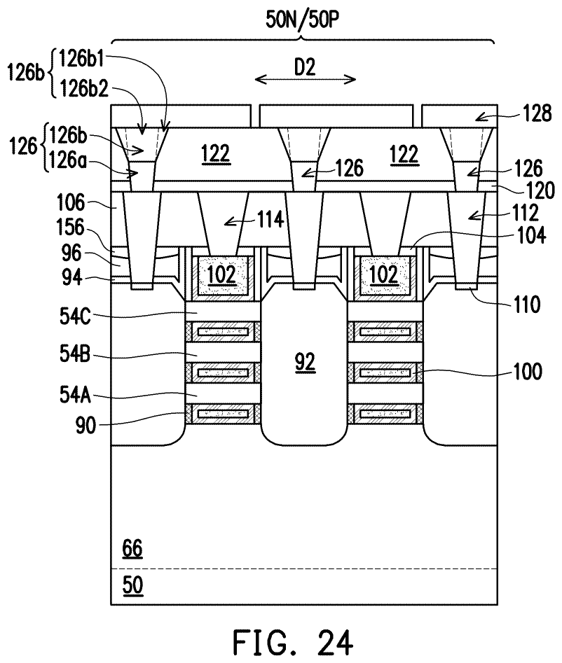

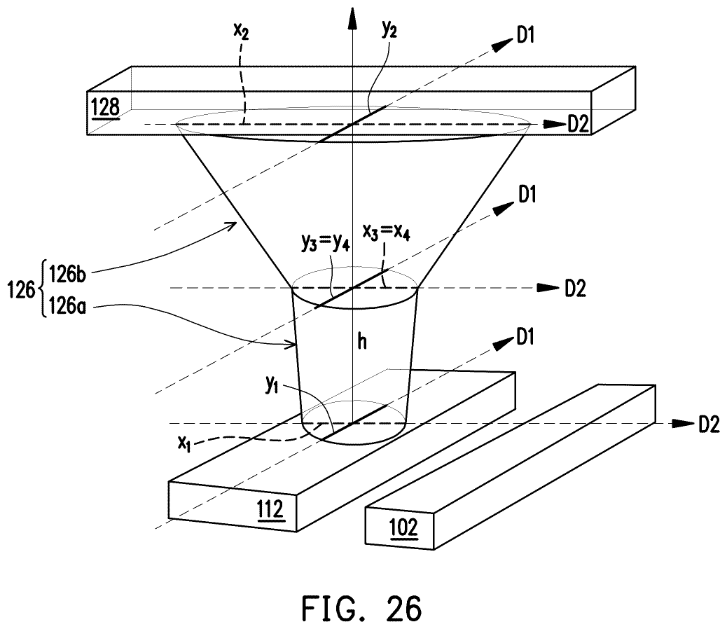

FIG. 24 illustrate a cross-sectional view of a nano-FET, in accordance with some alternative embodiments. Referring to FIG. 23B, FIG. 24 and FIG. 26, the nano-FET shown in FIG. 24 is similar to the nano-FET shown in FIG. 23B except that the bottom widths x₄ and y₄ of the upper parts 126b of the upper tier source/drain contact structures 126 substantially equal to the top widths x₃ and y₃ of the lower parts 126a of the upper tier source/drain contact structures 126.

In accordance with some embodiments of the present disclosure, a contact structure electrically connected between an underlying source/drain region and an overlying interconnect wiring is provided. The contact structure includes a lower part and an upper part disposed on the lower part. The lower part is electrically connected to the underlying source/drain region, and the upper part is electrically connected to the overlying interconnect wiring. The upper part has a first top width in a widthwise direction of the overlying interconnect wiring, the upper part has a second top width in a lengthwise direction of the overlying interconnect wiring, and the second top width of the upper part is greater than the first top width of the upper part.

In accordance with some other embodiments of the present disclosure, a structure including a transistor, an interlayer dielectric layer, a source/drain contact structure, and an interconnect wiring is provided. The transistor includes a gate and a source/drain region, wherein the gate and the source/drain region extend in a first direction. The interlayer dielectric layer covers the transistor. The source/drain contact structure is embedded in the interlayer dielectric layer, wherein the source/drain contact structure electrically connected to the source/drain region. The source/drain contact structure includes a lower part electrically connected to the source/drain region and an upper part disposed on the lower part, wherein the upper part has a first top width in the first direction, the upper part has a second top width in a second direction different from the first direction, and the second top width of the upper part is greater than the first top width of the upper part. The interconnect wiring is disposed on the interlayer dielectric layer, wherein the interconnect wiring extends in the second direction, and the interconnect wiring lands on the upper part of the source/drain contact structure.

In accordance with some alternative embodiments of the present disclosure, A method including following steps is disclosed. A transistor is formed over a substrate, wherein the transistor includes a gate and a source/drain region, and the gate and the source/drain region extend in a first direction. An interlayer dielectric layer is formed to cover the transistor. A contact opening is formed in the interlayer dielectric layer. An anisotropic etch process is performed to expand a first dimension of an upper portion of the contact opening in the first direction. A source/drain contact structure is formed in the contact opening, wherein the source/drain contact structure electrically connected to the source/drain region, and the source/drain contact structure comprising: a lower part electrically connected to the source/drain region; an upper part disposed on the lower part, wherein the upper part has a first top width in the first direction, the upper part has a second top width in a second direction different from the first direction, and the second top width of the upper part is greater than the first top width of the upper part. An interconnect wiring is formed on the interlayer dielectric layer, wherein the interconnect wiring lands on the upper part of the source/drain contact structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A contact structure electrically connected between an underlying source/drain region and an overlying interconnect wiring, the contact structure comprising:
a lower part electrically connected to the underlying source/drain region; and
an upper part disposed on the lower part and electrically connected to the overlying interconnect wiring, wherein the upper part has a first top width in a widthwise direction of the overlying interconnect wiring, the upper part has a second top width in a lengthwise direction of the overlying interconnect wiring, and the second top width of the upper part is greater than the first top width of the upper part.

2. The contact structure of claim 1, wherein the lower part is electrically connected to the underlying source/drain region, and the upper part is in contact with the overlying interconnect wiring.

3. The contact structure of claim 1, wherein the lower part has a first bottom width in the widthwise direction of the overlying interconnect wiring, the lower part has a second bottom width in the lengthwise direction of the overlying interconnect wiring, and a ratio of the second bottom width of the lower part to the first bottom width of the lower part ranges from about 0.9 to about 1.1.

4. The contact structure of claim 3, wherein the first top width of the upper part is greater than the first bottom width of the lower part, and the second top width of the upper part is greater than the second bottom width of the lower part.

5. The contact structure of claim 3, wherein a ratio of the second top width of the upper part to the first top width of the upper part is greater than 1.1.

6. The contact structure of claim 1, wherein
the upper part has a first bottom width in the widthwise direction of the overlying interconnect wiring, the upper part has a second bottom width in the lengthwise direction of the overlying interconnect wiring, and
the first bottom width of the upper part substantially equals to the first top width of the lower part, and the second bottom width of the upper part substantially equals to the second top width of the lower part.

7. The contact structure of claim 1, wherein
the upper part has a first bottom width in a widthwise direction of the overlying interconnect wiring, the upper part has a second bottom width in a lengthwise direction of the overlying interconnect wiring, and
the first bottom width of the upper part is greater than the first top width of the lower part, and the second bottom width of the upper part is greater than the second top width of the lower part.

8. The contact structure of claim 1, wherein a height of the lower part ranges from about 2 nanometers to about 10 nanometers.

9. The contact structure of claim 1 further comprising:
a contact etch stop layer; and
an interlayer dielectric layer covering the contact etch stop layer.

10. The contact structure of claim 9, wherein the height of the lower part is greater than a thickness of the contact etch stop layer.

11. The contact structure of claim 9, wherein the upper part is in contact with the interlayer dielectric layer, and the lower part is in contact with the interlayer dielectric layer and the contact etch stop layer.

12. A structure, comprising:
a transistor comprising a gate and a source/drain region, wherein the gate and the source/drain region extend in a first direction;
an interlayer dielectric layer covering the transistor;
a source/drain contact structure embedded in the interlayer dielectric layer, wherein the source/drain contact structure electrically connected to the source/drain region, and the source/drain contact structure comprising:
a lower part electrically connected to the source/drain region;
an upper part disposed on the lower part, wherein the upper part has a first top width in the first direction, the upper part has a second top width in a second direction different from the first direction, and the second top width of the upper part is greater than the first top width of the upper part; and
an interconnect wiring disposed on the interlayer dielectric layer, wherein the interconnect wiring extends in the second direction, and the interconnect wiring lands on the upper part of the source/drain contact structure.

13. The structure of claim 12, wherein
a ratio of the second top width of the upper part to the first top width of the upper part is greater than 1.1,
the lower part has a first bottom width in the first direction, the lower part has a second bottom width in the second direction, and a ratio of the second bottom width of the lower part to the first bottom width of the lower part ranges from about 0.9 to about 1.1.

14. The structure of claim 12, wherein
the upper part has a first bottom width in a widthwise direction of the overlying interconnect wiring, the upper part has a second bottom width in a lengthwise direction of the overlying interconnect wiring, and
the first bottom width of the upper part substantially equals to the first top width of the lower part, and the second bottom width of the upper part substantially equals to the second top width of the lower part.

15. The structure of claim 12, wherein
the upper part has a first bottom width in the widthwise direction of the overlying interconnect wiring, the upper part has a second bottom width in the lengthwise direction of the overlying interconnect wiring, and
the first bottom width of the upper part is greater than the first top width of the lower part, and the second bottom width of the upper part is greater than the second top width of the lower part.

16. The structure of claim 12, wherein the first direction is perpendicular to the second direction.

17. A method, comprising:
forming a transistor over a substrate, the transistor comprising a gate and a source/drain region, wherein the gate and the source/drain region extend in a first direction;
forming an interlayer dielectric layer to cover the transistor;
forming a contact opening in the interlayer dielectric layer;
performing an anisotropic etch process to expand a first lateral dimension of an upper portion of the contact opening in the first direction;
forming a source/drain contact structure in the contact opening, wherein the source/drain contact structure electrically connected to the source/drain region, and the source/drain contact structure comprising: a lower part electrically connected to the source/drain region; an upper part disposed on the lower part, wherein the upper part has a first top width in the first direction, the upper part has a second top width in a second direction different from the first direction, and the second top width of the upper part is greater than the first top width of the upper part; and
forming an interconnect wiring on the interlayer dielectric layer, wherein the interconnect wiring lands on the upper part of the source/drain contact structure.

18. The method of claim 17, wherein the anisotropic etch process comprises using a plasma controlled by electric field to expand the first lateral dimension of the upper portion of the contact opening in the first direction.

19. The method of claim 17, wherein a second lateral dimension of the upper portion of the contact opening in the second direction remains after performing the anisotropic etch process.

20. The method of claim 17, wherein
a ratio of the second top width of the upper part to the first top width of the upper part is greater than 1.1, and
the lower part has a first bottom width in the first direction, the lower part has a second bottom width in the second direction, and a ratio of the second bottom width of the lower part to the first bottom width of the lower part ranges from about 0.9 to about 1.1.
